(19) United States
(12) Patent Application Publication
(10) Pub. No.: US 2010/0201114 A1
(43) Pub. Date: Aug. 12, 2010

(54) PAGE MARK-UP USING PRINTED DOT BARCODES

(75) Inventors: Andrew James Fields, Cremorne (AU); Shaun Peter O'Keefe, Artarmon (AU)

Correspondence Address: FITZPATRICK CELLA HARPER & SCINTO, 1290 Avenue of the Americas, NEW YORK, NY, 10104-3800, US

(73) Assignee: CANON KABUSHIKI KAISHA, TOKYO (JP)

(21) Appl. No.: 12/630,059

(22) Filed: Dec. 3, 2009

(30) Foreign Application Priority Data
Dec. 10, 2008 (AU) 2008255212

(51) Int. Cl. B42D 15/00; B41J 2/01; H03M 1/22

(52) U.S. Cl. 283/70; 283/93; 347/107; 341/3

(57) ABSTRACT

Disclosed is a method (700) of creating a security document (310), the method comprising the steps of encoding the document (310) with a first set (309) of protection marks containing information defining an absolute co-ordinate system (314) across the face of the document (310), and encoding the document (310) with a second set (302) of protection marks containing information that (i) identifies at least one region (605) of the document (310) according to the co-ordinate system (314) and (ii) defines at least one security attribute of the content within the defined region (605), wherein the first (309) and second (302) sets of protection marks are intermixed across the face of the document (310) and are used together to determine the location of the defined region (605) within the document.

### CROSS-REFERENCE TO RELATED PATENT APPLICATIONS

This application claims the right of priority under 35 U.S.C. §119 based on Australian Patent Application No. 2008255212, filed 10 Dec. 2008, which is incorporated by reference herein in its entirety as if fully set forth herein.

### TECHNICAL FIELD OF THE INVENTION

The present invention relates generally to the protection of documents against tampering.

### BACKGROUND

It is often desirable to be able to identify a region or regions of a document which relate to the security of the document, or to the workflow progression of the document. It is also desirable to be able to handle the content of these regions, whether this content is printed content present in the original document or handwritten content added to the document by a user, according to the security status of the noted regions.

One example of a document for which such capabilities is desired is a contract that has been agreed upon, signed and dated by the involved parties. Alterations of the date, signature, or clauses within the contract may result in considerable financial loss or some other detriment to the signatories, and hence it would be advantageous to tamper protect regions of the document. There are typically areas on the document which are of particular interest to the user, and hence of high importance when detecting tampering (i.e. unauthorised amendments). Other areas of the document not contained in these regions may be of no importance, or possibly of less importance.

Another example of a document whose security is of interest is a form that a user completes with personal information, where the completed form is then to be processed automatically by a document processing system. Again, there are typically areas on the document, known as input fields, which are of particular interest to the user and hence of high importance when detecting additions. Other areas of the document not contained in these regions may be of no importance, or possibly of less importance.

Another example of a document whose security is of interest is a document that contains regions of confidential information that are only to be viewed by users with a certain security clearance. It is of importance to identify these regions, as well as provide information about the security clearance required to view these areas.

It is desirable when processing these regions, that processing be performed automatically with limited user input, and ideally in a completely autonomous fashion. It is hence necessary for the regions of interest in the document to be automatically identifiable and for the information about these regions to be accessible in some convenient fashion.

One current method addressing these requirements uses two dimensional “2D” barcodes on a document to provide information about the locations of regions of interest in the document, as well as some facility for acquiring information about the regions in question from a centralised information source. The term “barcodes” is used to denote any type of information incorporated into the document in question for security purposes. The limitation with such methods is that a central database of documents must be accessed and maintained. Accessing the database may not be convenient in some use cases, and considerable overhead is incurred in maintaining the database.

Other approaches use special inks and printing processes where, for example, “invisible” inks readable by infra-red readers are required.

Another method involves altering some property of parts of the document, such as text, in a recognizable fashion so as identify those parts of the document as belonging to regions of interest. A limitation of this method is that only a very small amount of information about how the regions are to be processed may be encoded. The method is usually limited to identifying an area of the page as being inside a region or outside of a region, resulting in a very limited scope for further workflow solutions.

### SUMMARY

It is an object of the present invention to substantially overcome, or at least ameliorate, one or more disadvantages of existing arrangements.

Disclosed are arrangements, referred to as Document Based Security (DBS) arrangements, which seek to address the above problems by enabling defined regions of interest on a document to be protected by encoding the document with two sets of protection marks, intermixed with each other across the document, at least some of which are suitably modulated in order to define the regions and the required aspects of protection.

According to a first aspect of the present invention, there is provided a method of creating a security document, the method comprising the steps of:

(a) encoding the document with a first set of protection marks containing information defining an absolute co-ordinate system across the face of the document; and

(b) encoding the document with a second set of protection marks containing information that (i) identifies at least one region of the document according to the co-ordinate system and (ii) defines at least one security attribute of the content within the defined region;

wherein the first and second sets of protection marks are intermixed across the face of the document and are used together to determine the location of the defined region within the document.

According to another aspect of the present invention, there is provided a document security system comprising:

an encoder for creating a security document, the encoder comprising:

(a) means for encoding the document with a first set of protection marks containing information defining an absolute co-ordinate system across the face of the document; and

(b) means for encoding the document with a second set of protection marks containing information that (i) identifies at least one region of the document according to the co-ordinate system and (ii) defines at least one security attribute of the content within the defined region;

wherein the first and second sets of protection marks are intermixed across the face of the document and are used together to determine the location of the defined region within the document; and

a decoder for verifying a received security document, the decoder comprising;

(c) means for detecting the first and second sets of protection marks;

(d) means for extracting the absolute coordinate system from the first set of detected marks;

(e) means for extracting the information that (i) identifies said at least one region of the document according to the co-ordinate system and (ii) defines said at least one security attribute of the content within the defined region from the second set of marks; and

(f) means for operating upon the extracted security attribute to thereby verify the received security document.

According to another aspect of the present invention, there is provided an encoder for creating a security document, the encoder comprising:

(a) means for encoding the document with a first set of protection marks containing information defining an absolute co-ordinate system across the face of the document; and

(b) means for encoding the document with a second set of protection marks containing information that (i) identifies at least one region of the document according to the co-ordinate system and (ii) defines at least one security attribute of the content within the defined region;

wherein the first and second sets of protection marks are intermixed across the face of the document and are used together to determine the location of the defined region within the document.

According to another aspect of the present invention, there is provided a computer program product including a computer readable storage medium having recorded thereon a computer program for directing a processor to execute a method for creating a security document, the program comprising:

(a) code for encoding the document with a first set of protection marks containing information defining an absolute co-ordinate system across the face of the document; and

(b) code for encoding the document with a second set of protection marks containing information that (i) identifies at least one region of the document according to the co-ordinate system and (ii) defines at least one security attribute of the content within the defined region;

wherein the first and second sets of protection marks are intermixed across the face of the document and are used together to determine the location of the defined region within the document.

Other aspects of the invention are also disclosed.

### BRIEF DESCRIPTION OF THE DRAWINGS

One or more embodiments of the invention will now be described with reference to the following drawings, in which:

FIGS. 1A and 1B form a schematic block diagram of a general purpose computer system upon which the arrangements described can be practiced;

FIG. 2 has been left intentionally blank;

FIG. 3 shows a portion of a security document;

FIG. 4 shows the modulation of a dot;

FIG. 5 shows the initial positions for the dots on a portion of the security document;

FIG. 6 shows an example of the layout of a page to be protected;

FIG. 7 is a flow diagram showing a method of encoding a security document;

FIGS. 8 and 9 show an arrangement for choosing the co-ordinate set and the image data set;

FIG. 10 is a flow diagram showing a process for assigning random values to grid cells;

FIG. 11 shows the grid of random numbers constituting the alignment grid;

FIG. 12 shows the protection dot grid offset into the absolute co-ordinate grid;

FIG. 13 is a flow diagram showing a process for encoding auxiliary data in a subset of the dots;

FIG. 14 is a flow diagram showing a process for encoding image data in a subset of the dots;

FIG. 15 shows the area used to calculate the average pixel intensity;

FIG. 16 shows a Region of Interest;

FIG. 17 shows the grid of image data values constituting the image data grid;

FIG. 18 shows a base 19 arrangement for encoding data;

FIG. 19 is a flow diagram showing a method of verifying (i.e. decoding) a received security document;

FIG. 20 is a flow diagram showing a process for detecting and grouping dots from a scan of a security document;

FIG. 24 is a flow diagram showing a process for establishing the absolute co-ordinates of the protection dot grid;

FIG. 26 is a flow diagram showing a process for recovering the encoded image data values;

FIG. 27 shows the altered area highlighted on the tampered document; and

FIG. 28 depicts a security document which has been altered in an unauthorised manner, after processing using the disclosed arrangements;

FIG. 29 depicts a typical layout for a workflow document;

FIG. 30 shows two different structures for calculating page properties;

FIG. 31 shows an alternate structure for calculating page properties;

FIG. 32 shows one possible header structure for a workflow document;

FIG. 33 shows an example of handwritten text being extracted from a document using the disclosed methods;

FIG. 34 is a flow diagram showing a process for extracting handwritten text from a document;

FIG. 35 shows one possible header structure for a secured access document;

FIG. 36 shows a secured access document with a secured access region masked out; and

FIG. 39 shows the modulation of a dot close up

### DETAILED DESCRIPTION INCLUDING BEST MODE

Where reference is made in any one or more of the accompanying drawings to steps and/or features, which have the same reference numerals, those steps and/or features have for the purposes of this description the same function(s) or operation(s), unless the contrary intention appears.

It is to be noted that the discussions contained in the “Background” section and that above relating to prior art arrangements relate to discussions of documents or devices which form public knowledge through their use. Such discussions should not be interpreted as a representation by the present inventor(s) or the patent applicant(s) that such documents or devices in any way form part of the common general knowledge in the art.

### INTRODUCTION

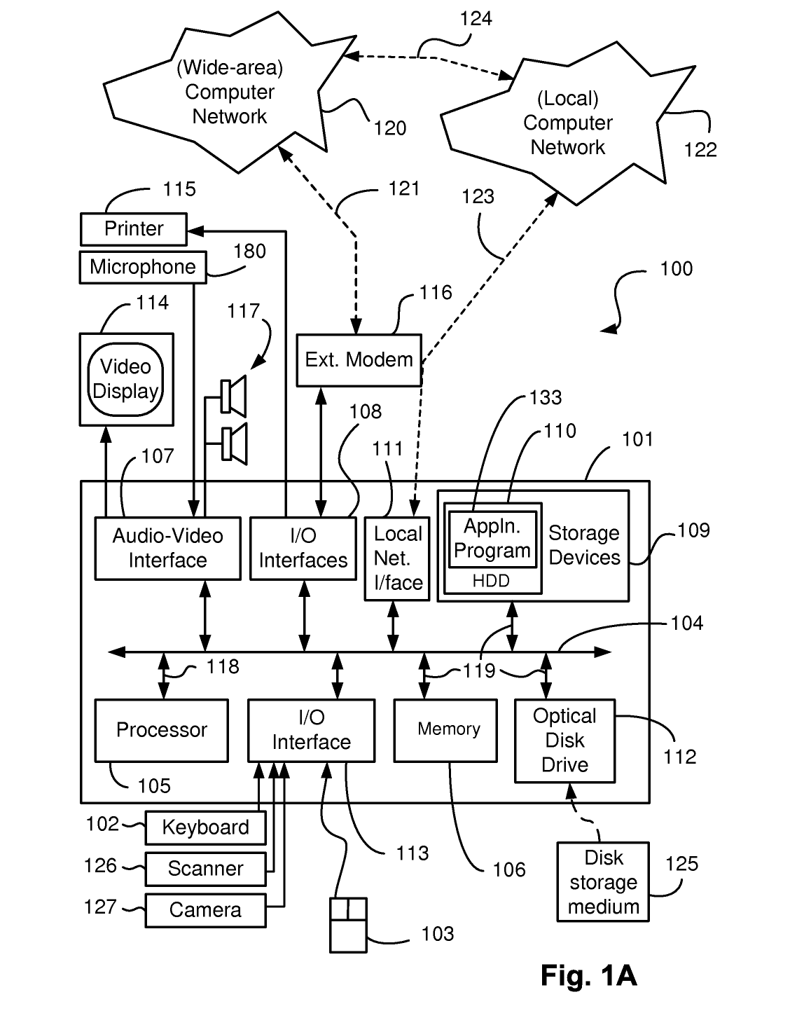

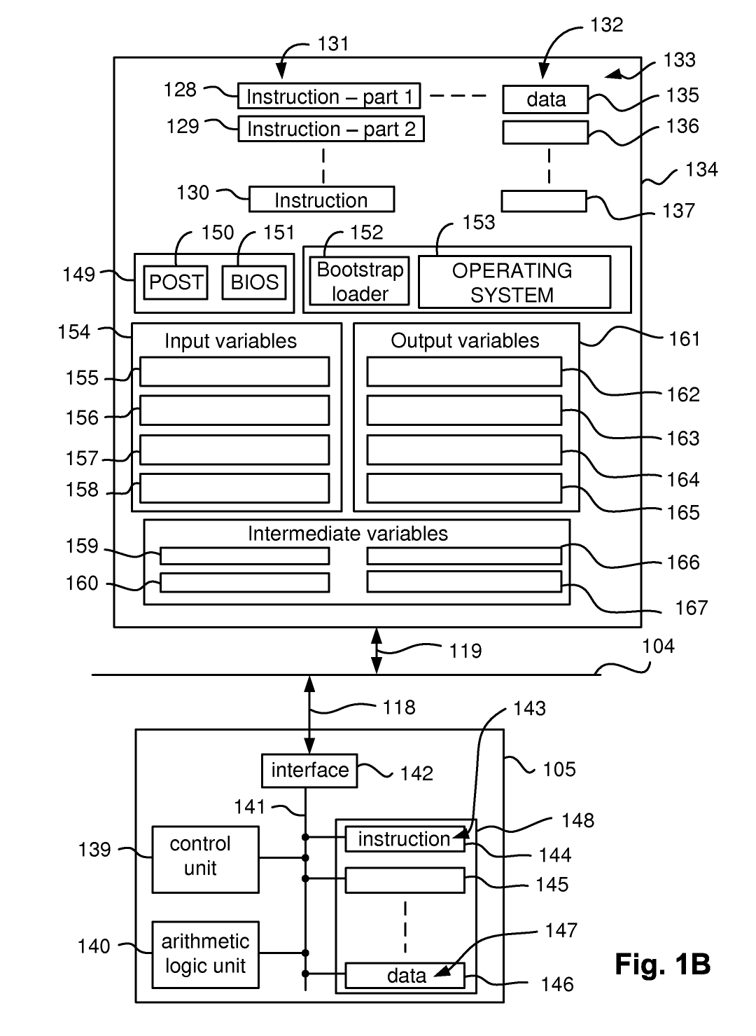

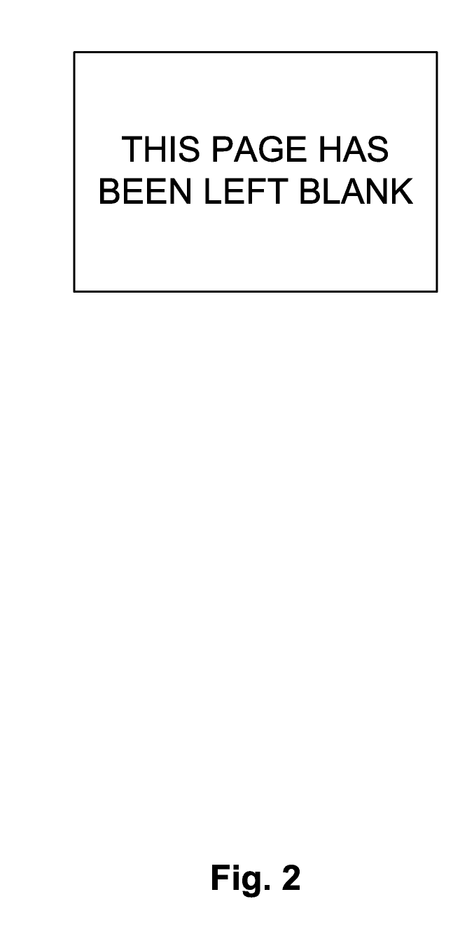

FIGS. 1A and 1B collectively form a schematic block diagram of a general purpose computer system 100, upon which the various arrangements described can be practiced.

As seen in FIG. 1A, the computer system 100 is formed by a computer module 101, input devices such as a keyboard 102, a mouse pointer device 103, a scanner 126, a camera 127, and a microphone 180, and output devices including a printer 115, a display device 114 and loudspeakers 117. The printer 115 may be in the form of an electro-photographic printer, an ink jet printer or the like. The printer may be used to print barcodes as described below. The scanner 126 may be in the form of a flatbed scanner, for example, which may be used to scan a barcode in order to generate a scanned image of the barcode. The scanner 126 may be configured within the chassis of a multi-function printer. An external Modulator-Demodulator (Modem) transceiver device 116 may be used by the computer module 101 for communicating to and from a communications network 120 via a connection 121. The network 120 may be a wide-area network (WAN), such as the Internet or a private WAN. Where the connection 121 is a telephone line, the modem 116 may be a traditional “dial-up” modem. Alternatively, where the connection 121 is a high capacity (eg: cable) connection, the modem 116 may be a broadband modem. A wireless modem may also be used for wireless connection to the network 120. In one arrangement, the printer 115 and/or scanner 126 may be connected to the computer module 101 via such communication networks.

The computer module 101 typically includes at least one processor unit 105, and a memory unit 106 for example formed from semiconductor random access memory (RAM) and semiconductor read only memory (ROM). The module 101 also includes an number of input/output (I/O) interfaces including an audio-video interface 107 that couples to the video display 114, loudspeakers 117 and microphone 180, an I/O interface 113 for the keyboard 102, mouse 103, scanner 126, camera 127 and optionally a joystick (not illustrated), and an interface 108 for the external modem 116 and printer 115. In some implementations, the modem 116 may be incorporated within the computer module 101, for example within the interface 108. The computer module 101 also has a local network interface 111 which, via a connection 123, permits coupling of the computer system 100 to a local computer network 122, known as a Local Area Network (LAN). As also illustrated, the local network 122 may also couple to the wide network 120 via a connection 124, which would typically include a so-called “firewall” device or device of similar functionality. The interface 111 may be formed by an Ethernet™ circuit card, a Bluetooth™ wireless arrangement or an IEEE 802.11 wireless arrangement.

The interfaces 108 and 113 may afford either or both of serial and parallel connectivity, the former typically being implemented according to the Universal Serial Bus (USB) standards and having corresponding USB connectors (not illustrated). Storage devices 109 are provided and typically include a hard disk drive (HDD) 110. Other storage devices such as a floppy disk drive and a magnetic tape drive (not illustrated) may also be used. An optical disk drive 112 is typically provided to act as a non-volatile source of data. Portable memory devices, such optical disks (eg: CD-ROM, DVD), USB-RAM, and floppy disks for example may then be used as appropriate sources of data to the system 100.

The components 105 to 113 of the computer module 101 typically communicate via an interconnected bus 104 and in a manner which results in a conventional mode of operation of the computer system 100 known to those in the relevant art. Examples of computers on which the described arrangements can be practised include IBM-PC's and compatibles, Sun Sparcstations, Apple Mac™ or alike computer systems evolved therefrom.

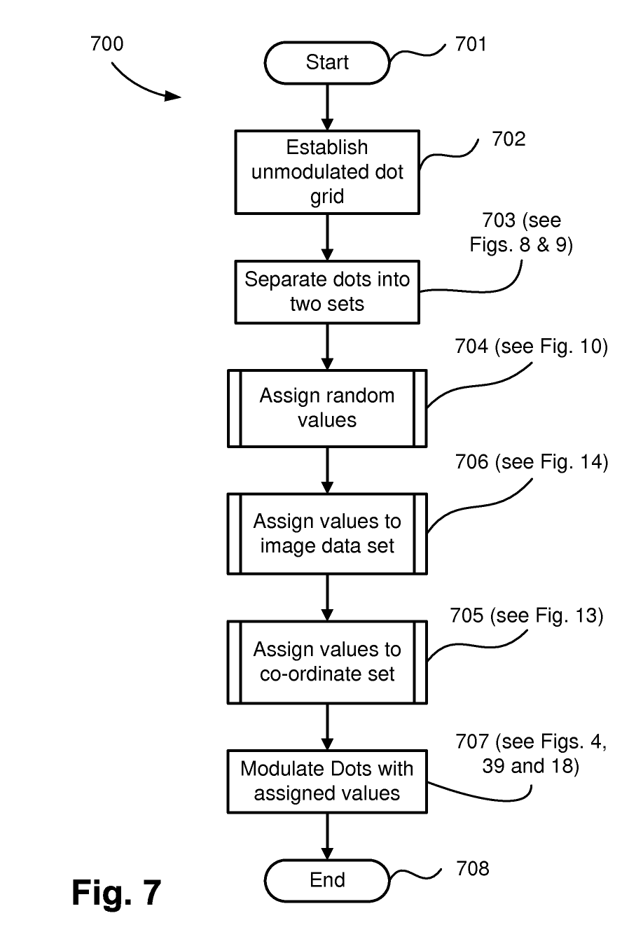

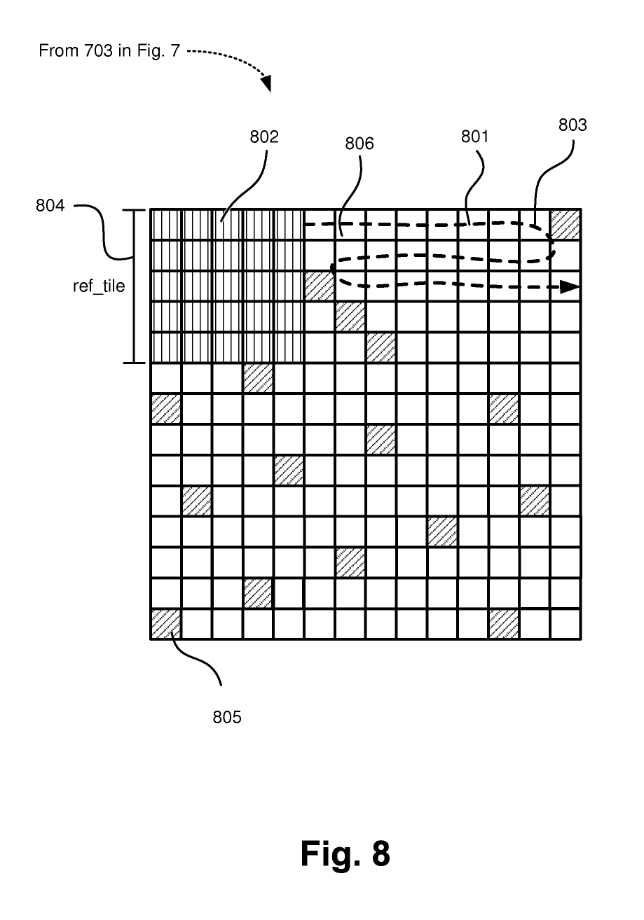

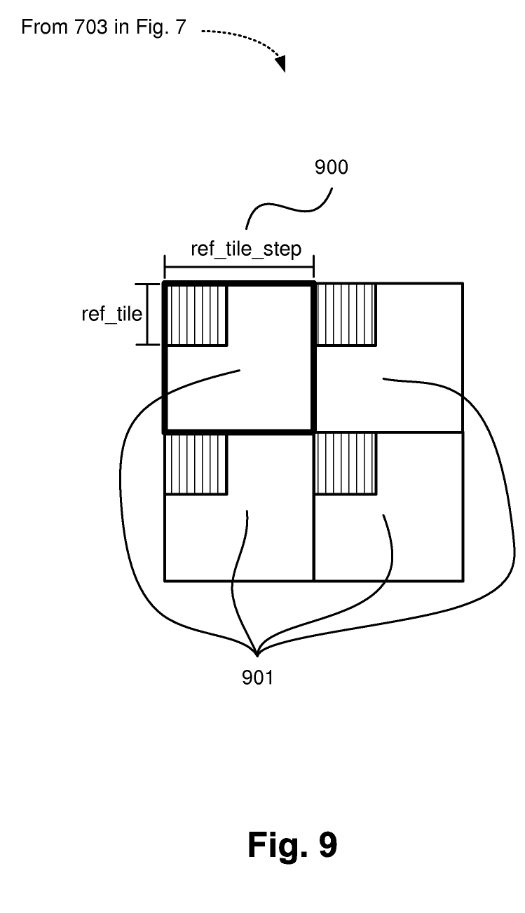

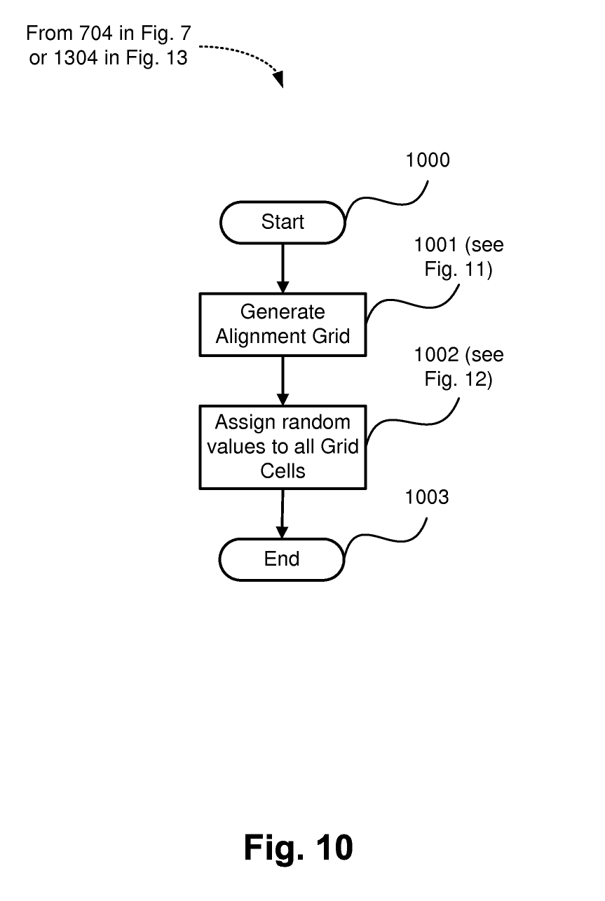

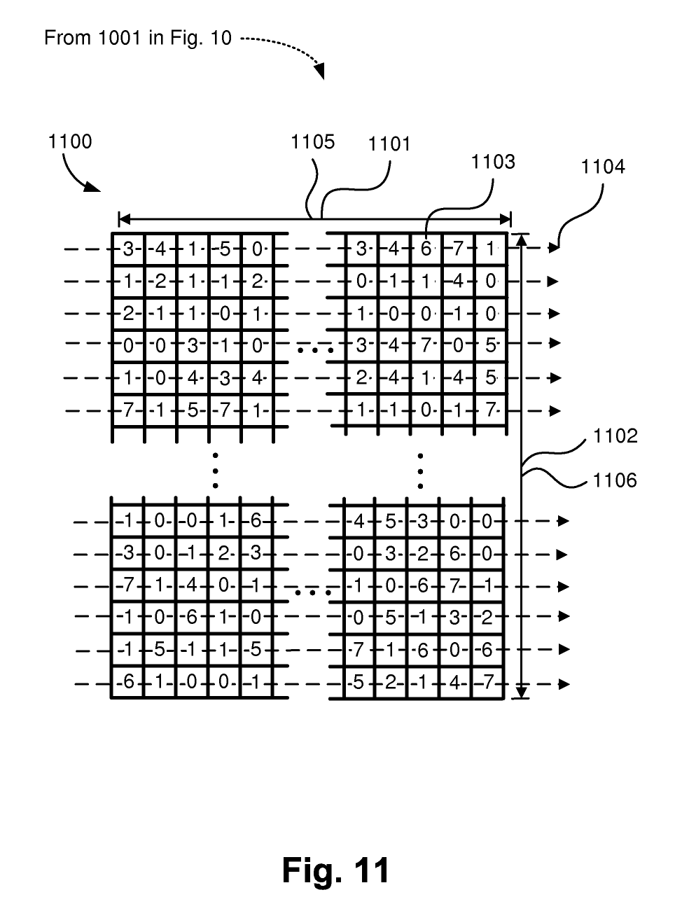

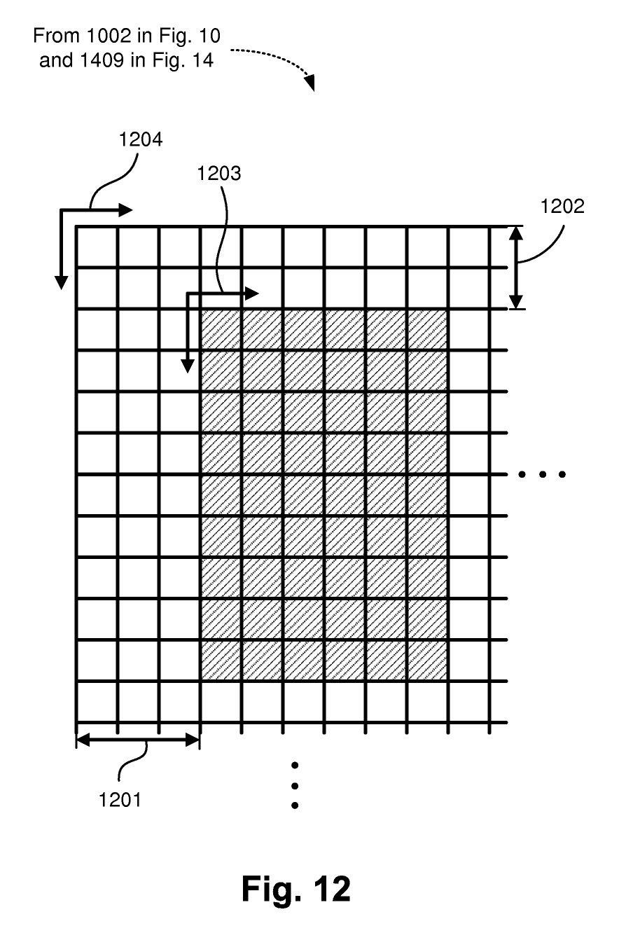

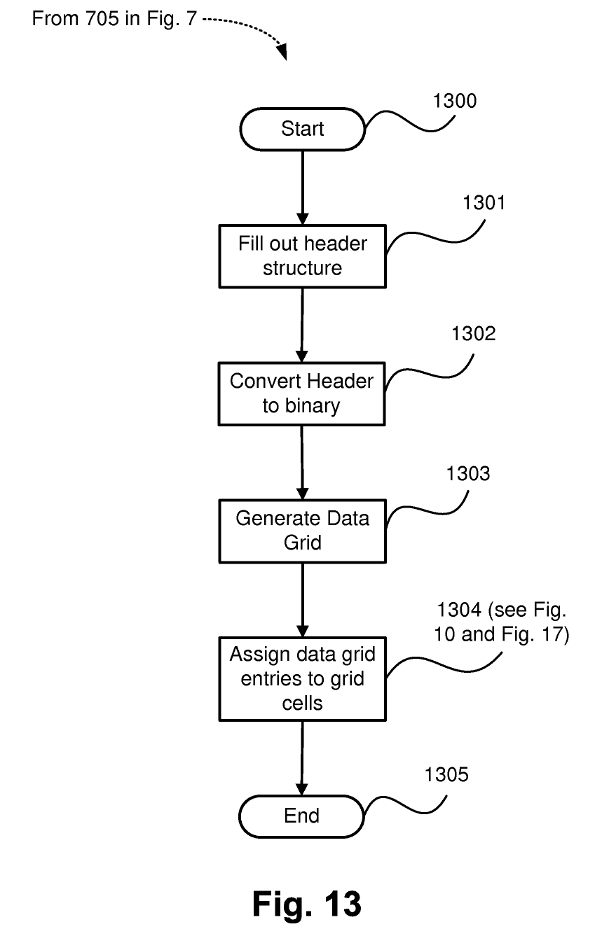

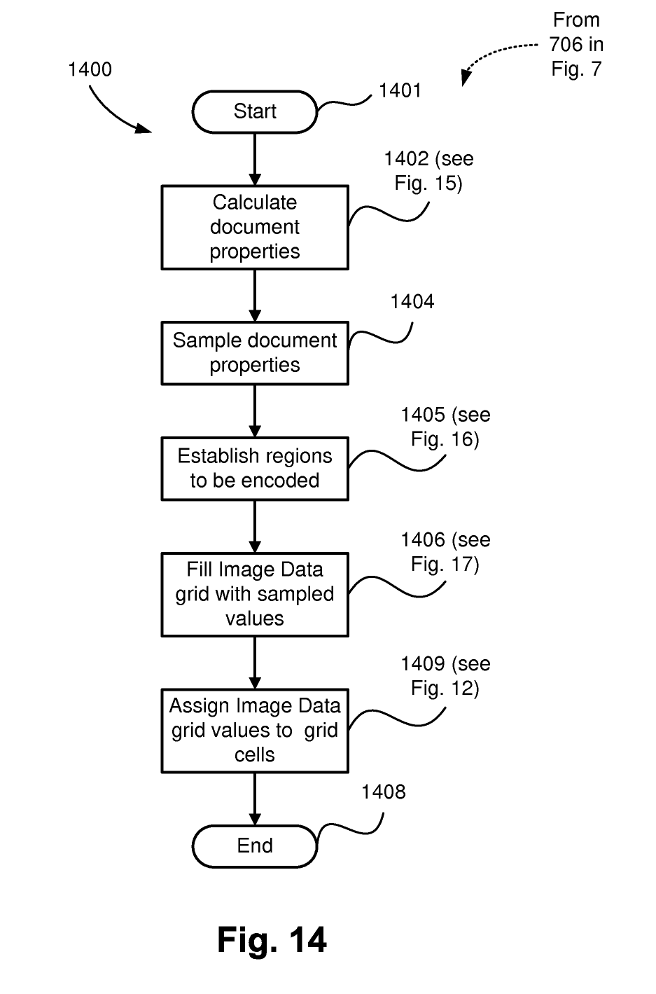

The DBS methods may be implemented using the computer system 100 wherein the processes of FIGS. 7, 10, 13-14, 19-20, 24-26 and 34 to be described, may be implemented as one or more software DBS application programs 133 executable within the computer system 100. In particular, the steps of the DBS method are effected by instructions 131 in the software 133 that are carried out within the computer system 100. The software instructions 131 may be formed as one or more code modules, each for performing one or more particular tasks. The DBS software may also be divided into two separate parts, in which a first part and the corresponding code modules performs the DBS methods and a second part and the corresponding code modules manage a user interface between the first part and the user.

The software 133 is generally loaded into the computer system 100 from a computer readable medium, and is then typically stored in the HDD 110, as illustrated in FIG. 1A, or the memory 106, after which the software 133 can be executed by the computer system 100. In some instances, the DBS application programs 133 may be supplied to the user encoded on one or more CD-ROM 125 and read via the corresponding drive 112 prior to storage in the memory 110 or 106. Alternatively the DBS software 133 may be read by the computer system 100 from the networks 120 or 122 or loaded into the computer system 100 from other computer readable media. Computer readable storage media refers to any storage medium that participates in providing instructions and/or data to the computer system 100 for execution and/or processing. Examples of such storage media include floppy disks, magnetic tape, CD-ROM, a hard disk drive, a ROM or integrated circuit, USB memory, a magneto-optical disk, or a computer readable card such as a PCMCIA card and the like, whether or not such devices are internal or external of the computer module 101. Examples of computer readable transmission media that may also participate in the provision of software, application programs, instructions and/or data to the computer module 101 include radio or infra-red transmission channels as well as a network connection to another computer or networked device, and the Internet or Intranets including e-mail transmissions and information recorded on Websites and the like.

The second part of the DBS application programs 133 and the corresponding code modules mentioned above may be executed to implement one or more graphical user interfaces (GUIs) to be rendered or otherwise represented upon the display 114. Through manipulation of typically the keyboard 102 and the mouse 103, a user of the computer system 100 and the DBS application may manipulate the interface in a functionally adaptable manner to provide controlling commands and/or input to the applications associated with the GUI(s). Other forms of functionally adaptable user interfaces may also be implemented, such as an audio interface utilizing speech prompts output via the loudspeakers 117 and user voice commands input via the microphone 180.

FIG. 1B is a detailed schematic block diagram of the processor 105 and a “memory” 134. The memory 134 represents a logical aggregation of all the memory devices (including the HDD 110 and semiconductor memory 106) that can be accessed by the computer module 101 in FIG. 1A.

When the computer module 101 is initially powered up, a power-on self-test (POST) program 150 executes. The POST program 150 is typically stored in a ROM 149 of the semiconductor memory 106. A program permanently stored in a hardware device such as the ROM 149 is sometimes referred to as firmware. The POST program 150 examines hardware within the computer module 101 to ensure proper functioning, and typically checks the processor 105, the memory (109, 106), and a basic input-output systems software (BIOS) module 151, also typically stored in the ROM 149, for correct operation. Once the POST program 150 has run successfully, the BIOS 151 activates the hard disk drive 110. Activation of the hard disk drive 110 causes a bootstrap loader program 152 that is resident on the hard disk drive 110 to execute via the processor 105. This loads an operating system 153 into the RAM memory 106 upon which the operating system 153 commences operation. The operating system 153 is a system level application, executable by the processor 105, to fulfil various high level functions, including processor management, memory management, device management, storage management, software application interface, and generic user interface.

The operating system 153 manages the memory (109, 106) in order to ensure that each process or application running on the computer module 101 has sufficient memory in which to execute without colliding with memory allocated to another process. Furthermore, the different types of memory available in the system 100 must be used properly so that each process can run effectively. Accordingly, the aggregated memory 134 is not intended to illustrate how particular segments of memory are allocated (unless otherwise stated), but rather to provide a general view of the memory accessible by the computer system 100 and how such is used.

The processor 105 includes a number of functional modules including a control unit 139, an arithmetic logic unit (ALU) 140, and a local or internal memory 148, sometimes called a cache memory. The cache memory 148 typically includes a number of storage registers 144-146 in a register section. One or more internal buses 141 functionally interconnect these functional modules. The processor 105 typically also has one or more interfaces 142 for communicating with external devices via the system bus 104, using a connection 118.

The DBS application program 133 includes a sequence of instructions 131 that may include conditional branch and loop instructions. The DBS program 133 may also include data 132 which is used in execution of the program 133. The instructions 131 and the data 132 are stored in memory locations 128-130 and 135-137 respectively. Depending upon the relative size of the instructions 131 and the memory locations 128-130, a particular instruction may be stored in a single memory location as depicted by the instruction shown in the memory location 130. Alternately, an instruction may be segmented into a number of parts each of which is stored in a separate memory location, as depicted by the instruction segments shown in the memory locations 128-129.

In general, the processor 105 is given a set of instructions which are executed therein. The processor 105 then waits for a subsequent input, to which it reacts to by executing another set of instructions. Each input may be provided from one or more of a number of sources, including data generated by one or more of the input devices 102, 103, data received from an external source across one of the networks 120, 122, data retrieved from one of the storage devices 106, 109 or data retrieved from a storage medium 125 inserted into the corresponding reader 112. The execution of a set of the instructions may in some cases result in output of data. Execution may also involve storing data or variables to the memory 134.

The disclosed DBS arrangements use input variables 154, that are stored in the memory 134 in corresponding memory locations 155-158. The DBS arrangements produce output variables 161, that are stored in the memory 134 in corresponding memory locations 162-165. Intermediate variables may be stored in memory locations 159, 160, 166 and 167.

The register section 144-146, the arithmetic logic unit (ALU) 140, and the control unit 139 of the processor 105 work together to perform sequences of micro-operations needed to perform “fetch, decode, and execute” cycles for every instruction in the instruction set making up the DBS program 133. Each fetch, decode, and execute cycle comprises:

(a) a fetch operation, which fetches or reads an instruction 131 from a memory location 128;

(b) a decode operation in which the control unit 139 determines which instruction has been fetched; and

(c) an execute operation in which the control unit 139 and/or the ALU 140 execute the instruction.

Thereafter, a further fetch, decode, and execute cycle for the next instruction may be executed. Similarly, a store cycle may be performed by which the control unit 139 stores or writes a value to a memory location 132.

Each step or sub-process in the processes of FIGS. 7, 10, 13-14, 19-20, 24-26 and 34 is associated with one or more segments of the DBS program 133, and is performed by the register section 144-147, the ALU 140, and the control unit 139 in the processor 105 working together to perform the fetch, decode, and execute cycles for every instruction in the instruction set for the noted segments of the program 133.

The DBS method may alternatively be implemented in dedicated hardware such as one or more gate arrays and/or integrated circuits performing the DBS functions or sub functions. Such dedicated hardware may also include graphic processors, digital signal processors, or one or more microprocessors and associated memories. If gate arrays are used, the process flow charts in FIGS. 7, 10, 13-14, 19-20, 24-26 and 34 may be converted to Hardware Description Language (HDL) form. This HDL description may be converted to a device level netlist which is used by a Place and Route (P&R) tool to produce a file which is downloaded to the gate array to program it with the design specified in the HDL description.

A document to be protected (referred to as an “original” or “unprotected” document), as described below, may be stored in an electronic file of a file-system configured within the memory 106 or the hard disk drive 110 of the computer module 101, for example. Similarly, the data read from a security document (also referred to as a “protected document”, which is an unprotected document after security features have been incorporated) may also be stored in the hard disk drive 110 or the memory 106 upon the security document being read by the DBS system shown in FIGS. 1A and 1B. Alternatively, the document to be protected may be generated on-the-fly by a software application program resident on the hard disk drive 110 and being controlled in its execution by the processor 105. The data read from a security document may also be processed by such an application program.

The digital representation of the document to be protected (ie the unprotected document) may be acquired by scanning the unprotected document using the scanner 126. Similarly, the data read from the security document (ie the protected document) may be acquired using the scanner 126. Information on the document in question that relates to the security of the document is referred to as “security information content” or alternately, as a “security feature”. Information on the unprotected document is referred to as “document information content”.

### Generating Security Documents

A document is secured by incorporating one or more sets of “protection marks” into the unprotected document to generate a security document. The protection marks are preferably low visibility to a human reader of the document. The protection marks are arranged to encode one or more security features which enable tamper detection, handwriting detection (i.e. a particular implementation of tamper detection which is optimized for detecting additions to the document information content) copy prevention, masking (also known as redaction) or other kinds of security or workflow applications.

The functionality provided by the security features is local to “regions” of the document. In other words the document carries information in the protection marks that enable accurate location of these regions in the face of damage to information on the protected document or damage to substrate of the protected document (ie damage to the physical medium upon which the document information content is printed). The functionality afforded by the security features does not require a centralised data source. Hence, information such as document content information (in the case of tamper-protection or handwriting detection) or region security status (in the case of masking) can be stored in the protection marks on the document.

This is an important feature of the DBS arrangements as it allows a protected document to be processed in a self-contained fashion, and eliminates the need to maintain a central repository of information about protected documents. This removes considerable costs from a document security system and allows the system to scale well with a large number of documents.

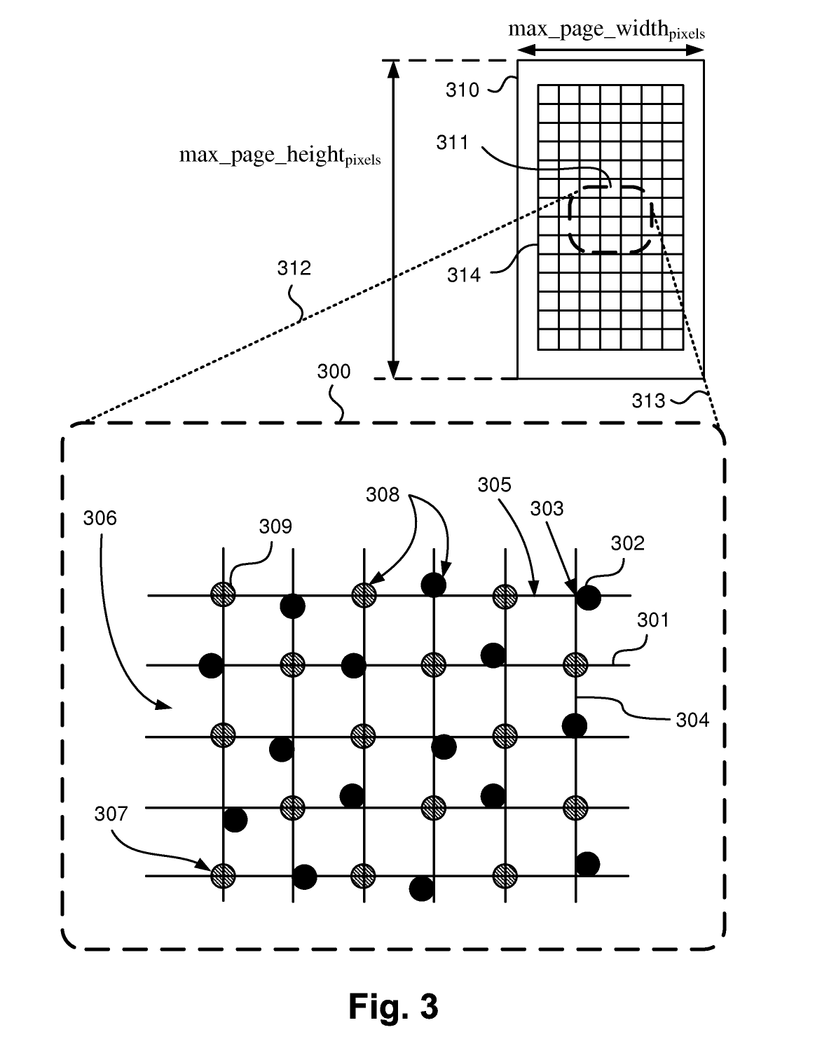

FIG. 3 shows an enlarged view 300 of part 311 of a document 310 after one of the aforementioned security features has been incorporated by incorporating modulated (ie encoded) protection marks into the document 310. The security feature consists of a large number of dots or marks 308 in an array 306, at least some of which have been modulated so as to incorporate security information content. The dots are separated into two different types of dots. A first type 309 are referred to as alignment dots and lie on grid intersections points of a fragment 305 of a regular square grid 314 referred to as a protection dot grid. The regular position of these alignment dots helps establish a reference map for defining the locations of a second type of dot. The second type of dot is referred to as a protection dot or more generally as a protection mark. Each protection dot 302 is located, in the present example, in the vicinity of a corresponding grid intersection point 303 of the fragment 305 of the regular square grid 314 formed by horizontal lines 301 and vertical lines 304. It is noted that it is the protection dots 302 that provide the protection, and not the grid 314. The grid 314 is depicted purely to provide a frame of reference for describing the location of the protection dots 302, and accordingly the grid 314 may be considered to be a “virtual” grid. A grid cell refers to a logical structure which comprises (a) a single intersection point 303 of the grid 314, (b) the associated protection dot 302, (c) an associated value or a series of associated values, and (d) the assigned value of the grid cell. Grid cells are physically bounded by alignment dots such as 309 on their four corners. Grid cells may be interchangeably viewed as either a data structure stored in a computer memory 106 containing the aforementioned values, or as a physical entity on a page.

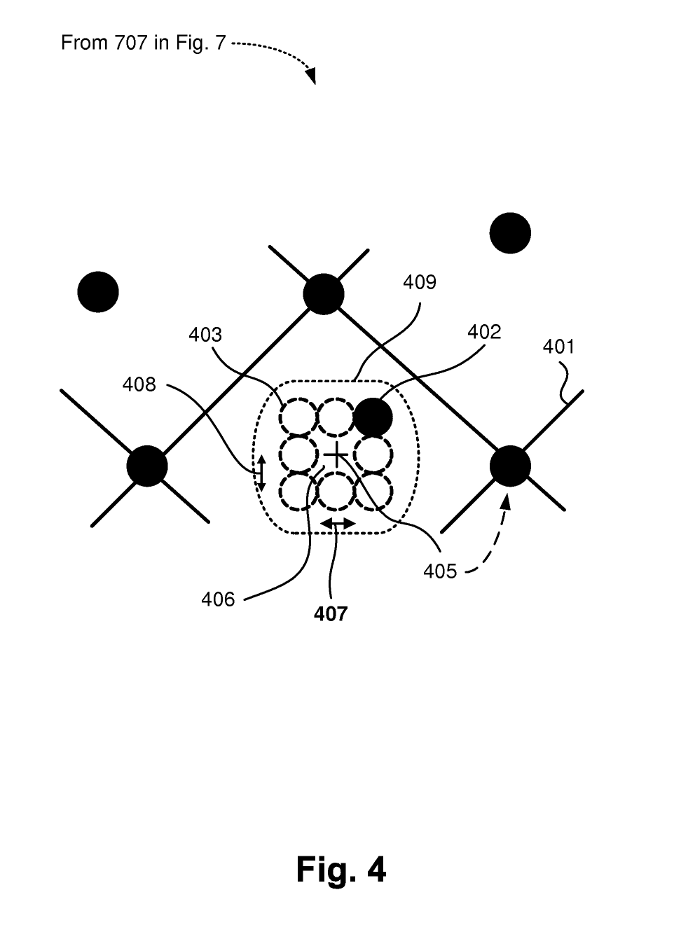

The positions of the protection dots 302 in the array 306 of protection dots are, in the present example, spatially modulated relative to the corresponding intersection points 303 of the grid fragment 305. The result of this modulation with regard to a particular protection dot is to move the dot (such as 402 in FIG. 4) to one of a number of positions (such as 403 in FIG. 4) which are at or in the vicinity of a corresponding grid intersection point 405. The grid intersection point 405 is shown in enlarged form by the dashed shape 409. The appearance of the array 306 of modulated protection dots in FIG. 3 is similar to that of a regular array of dots (i.e. an array of alignment dots each of which is situated on the corresponding grid intersection point of an associated regular square grid), but not identical.

The example described in relation to FIG. 3 involves modulation of a position attribute of the unmodulated protection dot. Other modulation schemes can be used which relate to other attributes of the protection dots. Thus, for example, intensity modulation of the protection dots can be used, or alternately, code based modulation using different symbols for the protection dots can be used. Furthermore, the protection marks may be visible to a person, in order to announce that the document is protected, and thus deter unauthorised amendments. However the protection marks may also be invisible to a person, provided that they can be detected by a decoding system.

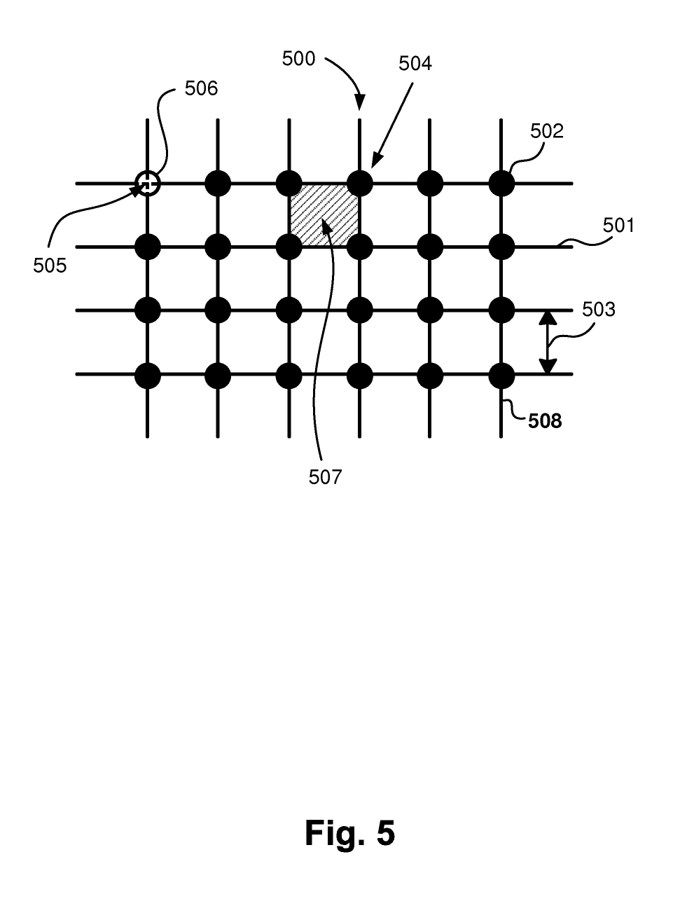

FIG. 5 shows the initial (spatially unmodulated) positions for the protection dots (alignment dots are not shown) on a portion of a document. In the described arrangement, these initial positions form an unmodulated array of protection dots associated with intersection points such as 505 of a regular square grid 500. The term “square grid” relates to the shape 507 that is described by horizontal lines 501 and vertical lines 508 of the grid 500. The grid 500 has a pitch 503 that is typically in the order of 1 mm While the described arrangements make use of rectangular, and preferably square, regular grid arrangements, other “regular” grid arrangements are possible. For example, grid arrangements having hexagonal or parallelogram grid shapes can be used. Furthermore, a grid formed by concentric circles and radii, which may be considered regular in terms of r and θ, can be used. What is required, and inferred by the use of the term “regular”, is that the grid intersection points (ie the positions upon which unmodulated protection marks are situated) be defined in a known manner, thereby enabling determination of the modulated values of modulated marks depending upon the type of encoding used. Accordingly, once the grid, or the manner in which the grid is formed, is known, then given the modulation scheme, the marks on an encoded document may be decoded.

### Selecting and Identifying Regions of Interest

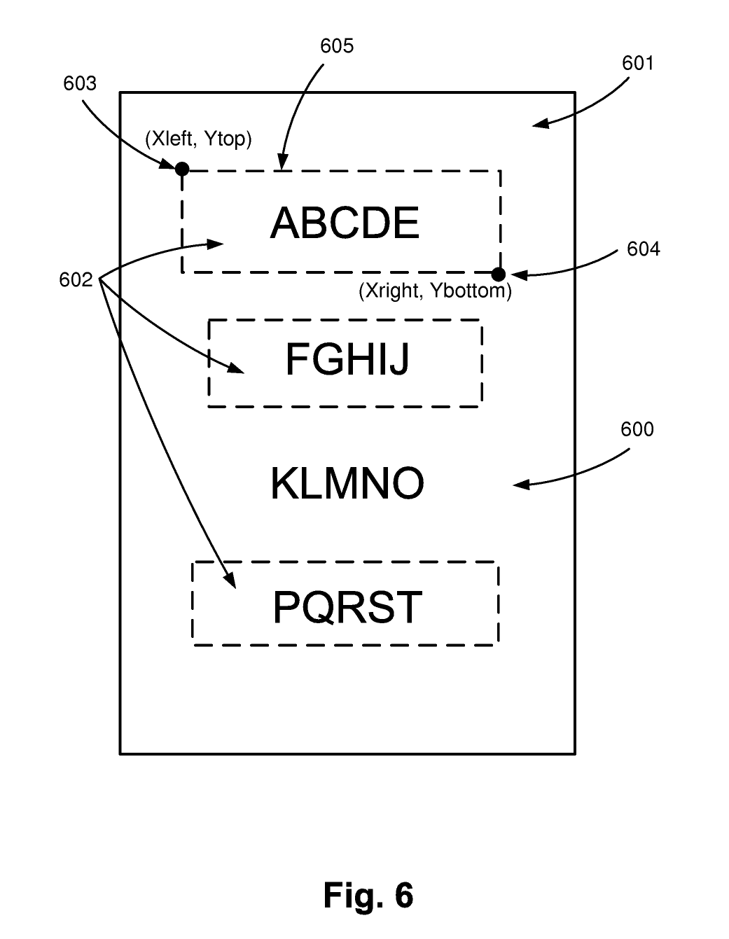

A typical layout of an unprotected document that is to be secured is shown in FIG. 6. The document consists of the substrate 601 (ie the physical medium upon which the document is printed), a foreground text area 600 and number of regions, being regions of interest 602 or ROI (plural or singular). The regions of interest 602 are selected by means of user input via the computer interface in FIG. 1A such as the mouse 103, or possibly the regions are determined using a predetermined template comprising a file stored in the memory 106.

Each of the ROI are bounded by a respective bounding box such as 605 which is defined by co-ordinates (X_{left}, Yₜₒₚ) 603 and (X_{right}, Y_{bottom}) 604. It should be noted that these bounding boxes are virtual and are not visible on the document to be protected. ROI of different shapes other than rectangles, such as circles, ellipses or complex geometric arrangements can also be used. The described DBS arrangements use rectangles for identifying regions of documents as they are simple to use, however algorithms using other shapes can be implemented by a person skilled in the art.

The ROI represent areas of the document whose content may be of particular importance in relation to the security of the document, or of interest in regard to workflow operations. As mentioned earlier, it is the purpose of the security features on the document to store both the location of these ROI as well as some security attribute of their content. The security attribute stored is most likely information about foreground text 600, as will be the case for the first DBS arrangement. Usage of this foreground information may vary based on the application, i.e. from anti-tamper to handwriting detection, and other possible applications. This first DBS arrangement focuses on the anti-tamper use case. It is also possible to store other security attributes besides information about the foreground text area, such as a representation of the paper substrate in the region. It is generally suggested that in order to take advantage of the capabilities of this DB S method, the security attribute comprise high volume dense image data, and the function be aimed at providing a second representation of the ROI for comparison with the ROI on the actual document. Of course, the term security attribute is not limited to being a representation of image data.

### First DBS Arrangement

A secure document is now described which provides anti-tamper protection for regions of the document.

### Assigning Types to Protection Dots

FIG. 7 is a flow chart of a process 700 for encoding and thus generating a security document (ie a protected document according to the DBS arrangement) using an encoder apparatus implementing a DBS arrangement. The process 700 commences with a start step 701, after which step 702 determines initial (i.e. spatially unmodulated) positions for the protection dots 502 in the array 504 of protection dots on the page in question in FIG. 5. The step 702 is performed by the processor 105 based upon input information stored in the memory 106 defining how the unmodulated positions of the protection dots are established. In a subsequent step 703 the protection dots are separated into two separate sets. The step 703 is performed by the processor 105 based upon input information stored in the memory 106 defining how the protection dots are to be separated. Although two sets of protection marks are described in the first DBS arrangement, this does not have to be the case, and more than two sets can be stored in the barcode.

In the first DBS arrangement, the protection dots are separated into two sets, being the co-ordinate set and the image data set. The co-ordinate set is a set of protection dots whose members encode a series of pseudo random values which are used to establish an absolute co-ordinate system over the grid cells of the page 310 (see FIG. 3), and also encodes a second auxiliary data channel which contains information about the location and types of ROI on the document. The image data set is a set of protection dots whose members encode the content (image or otherwise) within the ROI. While the auxiliary data channel is encoded with the co-ordinate set to save bandwidth, it may instead be encoded in a third set of dots, along with the image data set, or in a combination of the three. The co-ordinate set of protection marks and the image data set of protection marks are typically intermixed on the protected document.

The protection dots are divided between the two sets of protection dots dependant upon the intended usage of the security document. Essentially, a trade off is made between the number of ROI encoded and the total size (in information capacity) of the security attributes of the ROI that are encoded. If N_{cd} is the size of the co-ordinate set (in number of dots), and N_{dd} is the size of the image data set (also in number of dots), then K, being the dot membership ratio, is given by the following relationship:

K=N_{cd}−/N_{dd} [1]

If there is likely to be a large number of small ROI, then it has been found to be better to have a higher K. If there is likely to be a small number of large ROI then it has been found that a smaller K is best. In the first DBS arrangement, the ratio is set to a predefined constant value and assumes that the likely usage of the security document is known. As a simple extension for the case where the likely usage is not known, and the size and number of ROI is likely to vary, then an additional set of protection dots can be used to encode K, so that K may be varied from case to case.

In the first DBS arrangement, K is set to a constant value of 0.1 which has been found to perform well for 10 ROI the size of an average text field on a form. Other values are possible and deducible by those skilled in the art.

FIGS. 8 and 9 show one possible scheme for separating the two sets.

FIG. 8 depicts an array (also referred to as a “grid”) of grid cells 801. Protection dots assigned to a coordinate set are depicted in cross-hatch format, as shown by 805 for example. Protection dots assigned to an image data set are depicted in plain format, as shown by 806 for example.

Separating the protection dots is achieved in the current DBS arrangement by allocating, as depicted in FIG. 8, one protection dot such as 805 to a co-ordinate set, for every ten protection dots such as 806 allocated to a corresponding image data set. In the first DBS arrangement, a reference pattern 802 (also referred to as a “tile” 802), comprising a 5×5 sub-array of grid cells in the present example, is included to establish local context to assist in identifying which protection dots are in the co-ordinate set and which are in the image data set. The reference pattern 802 in the present example is a regular arrangement having dimensions of “ref_tile” (ie 804) by ref_tile grid cells (see FIG. 8), at a spacing of “ref_tile_step” 900 (see FIG. 9). Each ref_tile by ref_tile set of grid cells contains the same values (ie the same set of modulated protection marks).

This reference pattern is easily detected when the protection dots are decoded by virtue of the redundancy of the reference pattern. The reference pattern can survive considerable damage to the dots or the page. The purpose of the pattern is to establish a set of tiles 901 across the grid, which is used to establish a reference for assigning protection dots to sets so the inverse of the encoding step can be performed. The tile structure is not visible to the eye i.e. a user cannot distinguish a protection dots location within a tile by observation, nor do the tiles such as 901 represent independently decodable blocks of data i.e. although the protection dots are assigned to the alignment sets and data sets on a tile-by-tile basis, the protection dots from both tiles are used as a contiguous set of dots. The grid cells in each tile such as 806 are indexed in raster order (depicted by a dashed serpentine arrow 803) from index=0 to index=ref_tile_step²⁻ref_tile² where ref_tile_step²⁻ref_tile² is the total number of grid cells in a single tile available to be assigned to sets. Using this indexing method, each protection dot in the grid which is not part of the repeated pattern is assigned to the co-ordinate set if the modulus(10+1) of tile index is 0.

In another arrangement, a random selection process can be used where each protection dot is allocated to the co-ordinate set with a probability of 1/11. This alleviates problems of regular damage to the protection dot grid destroying a disproportionate number of one set or the other and changing K.

In yet another arrangement, the reference pattern can be removed entirely. The reference pattern is included in the main DB S arrangement to improve the performance of the decoding side of the algorithm, as will become apparent.

### Associating Values to Encode Co-ordinate System Information

Returning to FIG. 7 in a subsequent step 704, random values, which are used to establish a co-ordinate system, are associated with all grid cells, irrespective of whether the grid cells are in the co-ordinate set or image data set. This step is further detailed in FIG. 10.

FIG. 10 shows a flow chart of a process for associating a grid of values to the grid cells. The process commences at a step 1000 and in a subsequent step 1001, an “alignment grid” 1100 (which is depicted in FIG. 11 and which is to be distinguished from the “alignment dots” shown in FIG. 3, for example) is generated (see FIG. 11).

FIG. 11 depicts how the alignment grid is of dimensions align_grid_w (ie 1101) by align_grid_h (ie 1102). These dimensions are chosen based on the maximum expected size of the document. If dot_spacing_x and dot_spacing_y are both equal to 503 (see FIG. 5), align_grid_w and align_grid_h are defined by the following relationships:

align_grid_{—}w=max_page_widthₚᵢₓₑₗₛ/dot_spacing_{—}x [2]

align_grid_{—}h=max_page_heightₚᵢₓₑₗₛ/dot_spacing_y [3]

where max_page_widthₚᵢₓₑₗₛ and max_page_heightₚᵢₓₑₗₛ is are depicted in FIG. 3.

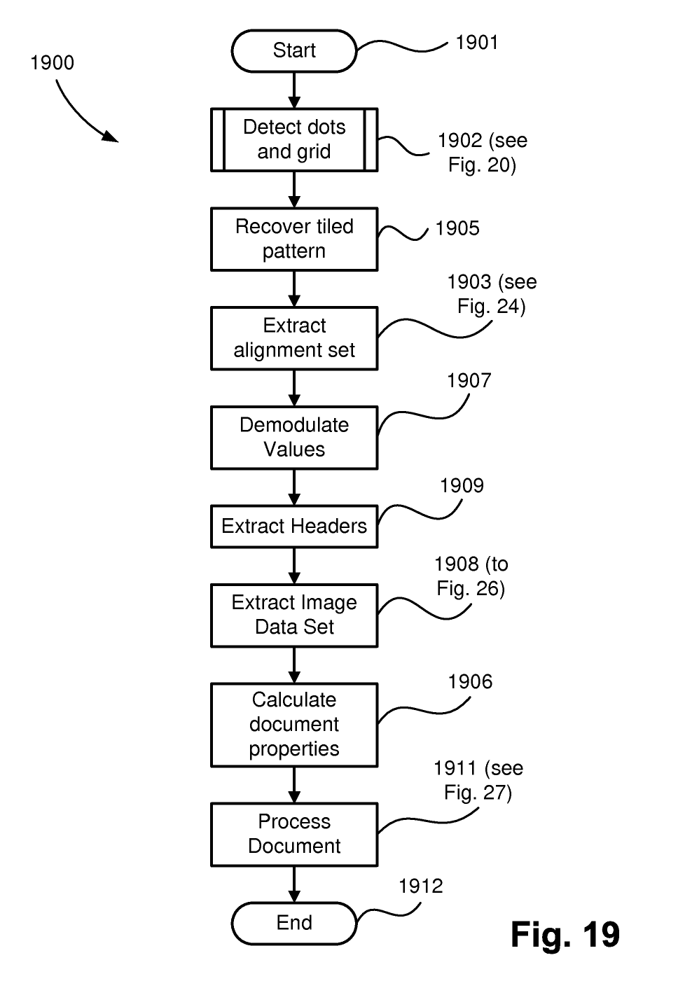

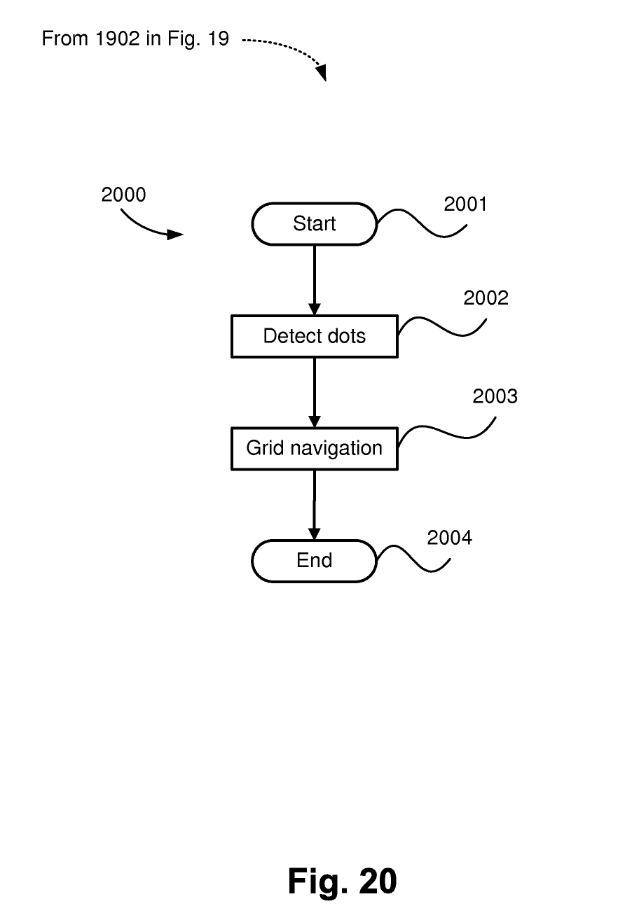

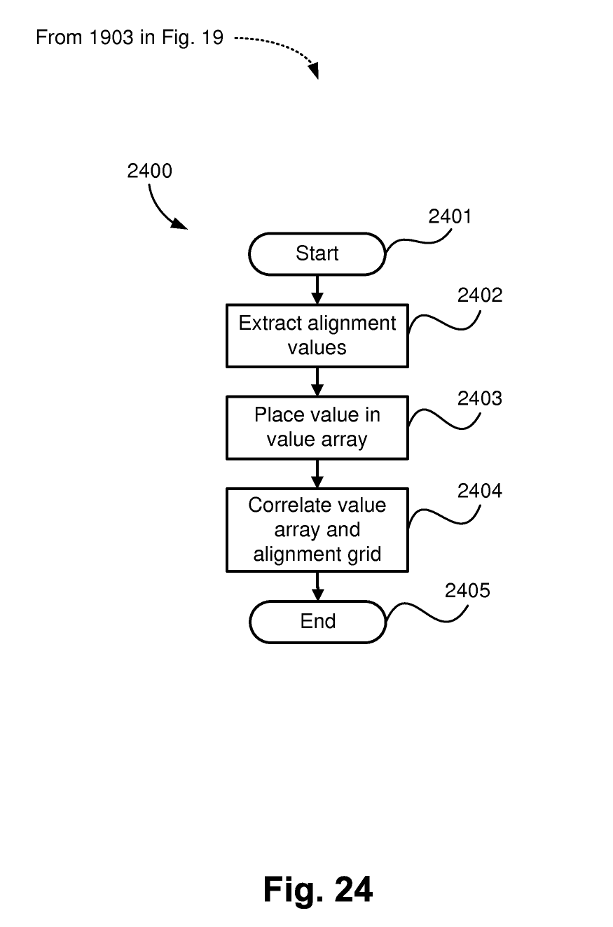

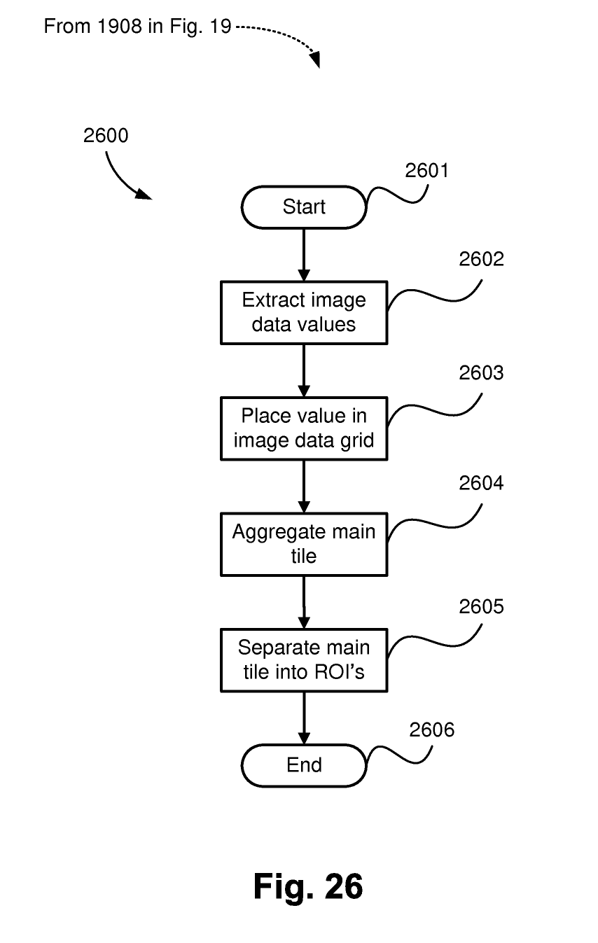

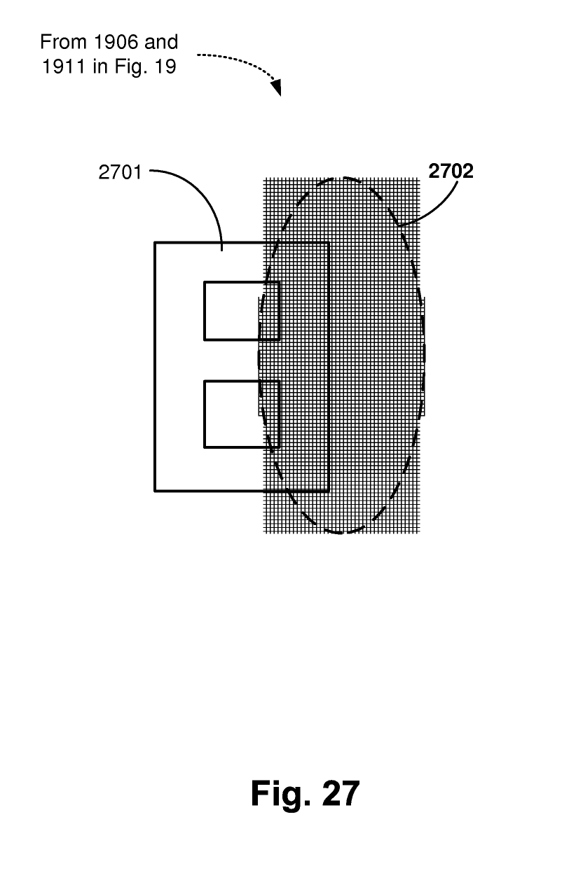

The alignment grid is then populated with a pseudo random sequence 1103, using a seed which is known to both encoding and decoding sides of the algorithm. In a practical system, this means that the seed is known both to the encoding and decoding platforms in the DBS system. The order specified by 1104 is used to populate the alignment grid. The co-ordinates of the cells in the alignment grid establish an absolute co-ordinate system for the security document which can be used for identifying the location of ROI on the document. The term “absolute coordinate system” means that there is a one to one mapping between coordinates in the coordinate system and the pixel-based content of the document information. The decoding process described in relation to FIG. 19 describes how this co-ordinate system is established from the pseudo random sequence.

Returning to FIG. 10 in a following step 1002 grid cells are associated with cells in the alignment grid. The protection dot grid is offset into the alignment grid by offsets x_grid_offset 1201 and y_grid_offset 1202 (see FIG. 12).

FIG. 12 shows how, in such a manner, each point in the protection dot grid at grid co-ordinates 1203 (ie grid_x, grid_y) is associated with the alignment grid cell at alignment grid co-ordinates 1204 (ie grid_x+x_grid_offset, grid_y+y_grid_offset) and hence is also associated with an absolute co-ordinate which is equal to the alignment grid co-ordinate, where grid_x is a variable of range 0 to max_page_widthₚᵢₓₑₗₛ/, grid_y is 0 to max_page_heightₚᵢₓₑₗₛ, x_grid_offset is a constant arbitrary value indicating the x location of the (0,0) co-ordinate of the grid cells, and y_grid_offset is a constant arbitrary value indicating the y location of the (0,0) co-ordinate of the grid cells.

Returning to FIG. 10 the process then terminates at a step 1003 and returns to the main process 700 in FIG. 7.

### Generate Image Data Information

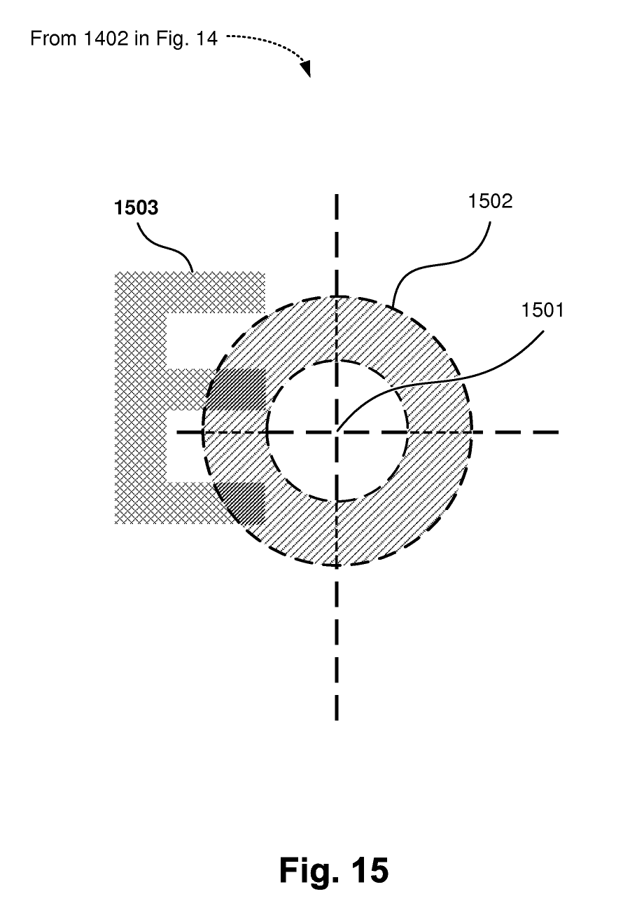

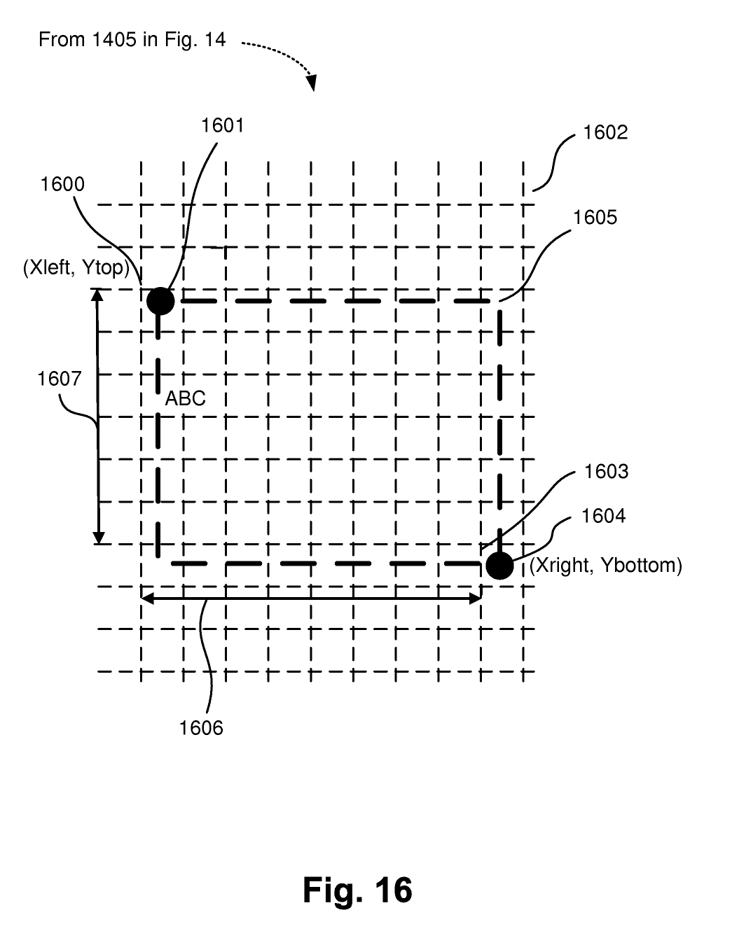

Returning to FIG. 7, in a subsequent step 706 image data values which encode one possible security attribute of the content of the ROI are associated with the image data set of dots. This process is further detailed in FIG. 14.

FIG. 14 shows how the process 1400 begins at 1401 and in a subsequent step 1402 the attributes of the ROI to be encoded in the image data set are calculated. In the first DBS arrangement, the image data set is used to provide tamper protection for the ROI, and each of the dots in the image data set encodes some attribute of the text within the ROI for comparison with the actual received protected document on decoding.

One such attribute is based upon average image intensity in an area of the ROI and is now described in regard to FIG. 15.

FIG. 15 shows the area used to calculate the average pixel intensity. To calculate this attribute, an ROI is first converted to a greyscale bitmap image. A filter function, such as a Gaussian blur, is applied to the greyscale bitmap image. The greyscale image is then binarised, by applying a threshold function, to form a black and white image.

The average pixel intensity of an annular area 1502 around each grid intersection point 1501 in the ROI is then determined and stored in the memory 106. Ideally the area 1502 is big enough that when it is sampled at the desired sampling frequency the area 1502 overlaps its adjacent area (not shown). In other words it is desirable that the area 1502 overlaps the annular areas (not shown) associated with grid intersection points in the neighbourhood of the area. Furthermore, it is possible for the area 1502 to overlap other areas that are associated with grid intersection points that are not adjacent. In the present example, the area 1502 encompasses part of a letter ‘E’ 1503. The average pixel intensity that is determined for the area 1502 is scaled, using a suitable scale factor, to one of the possible digital code values (also referred to as “intervals”) of the dot modulation scheme 409 (see FIG. 4).

As an extension to the DBS arrangement, the average pixel intensity may be determined at a resolution higher than the resolution of the grid intersection points. This can be done by interpolating between grid intersection points and sampling a number of extra points.

The sampling of points is referred to as the sampling frequency.

In FIG. 15 the attribute of the ROI that is used is the average pixel intensity. However, other attributes and other areas can also be used. For example, the area used can be circular, square, or any shape, or the union of a plurality of small areas in any shape. Other properties which can be used include different statistical measures of the pixel intensity, e.g. the median, maximum or standard deviation. By using a Fourier transform of the associated area, other properties such as the median frequency, centroid or peak positions can be used. Another property which can be used is the average direction of the lines in the associated area.

Returning to FIG. 14 a next step 1404 samples the ROI at a predefined sampling frequency for encoding. As mentioned, in the first DBS arrangement this frequency is the spacing of the grid intersection points belonging both protections dots 503. As an extension, it is also possible to sample from the grid intersection points of the alignment dots. Each sample is stored in memory in a two-dimensional image grid. The term “image grid” is used to denote the array of sampled values representing the document information content, according to the points sampled across the document according to the step 1404.

In a following step 1405, the location of the ROI are converted from pixel co-ordinates in the document to image grid co-ordinates.

As the ROI are initially selected from a full resolution image of the document via a user input, and each member of the ROI are defined in the first DB S arrangement by the pixel co-ordinates (X_{left}, Yₜₒₚ) 603 and (X_{right}, Y_{bottom}) 604 (see FIG. 6), it is necessary to convert from the pixel co-ordinates of the document to the new co-ordinate system of the image grid. Provided the image grid has been generated as per the methods detailed in previous steps, the following equations can be used to convert from pixel co-ordinates to image grid co-ordinates as follows:

X_{image}_{_{—}}_{grid}=floor(Xₚᵢₓₑₗ/grid_spacing+0.5) [5]

Y_{image}_{_{—}}_{grid}=floor(Yₚᵢₓₑₗ/grid_spacing+0.5) [6]

where X_{image}_{_{—}}_{grid} is the x co-ordinate in the image grid co-ordinate system, floor is the operation of rounding a decimal number to its lower integer value, Xₚᵢₓₑₗ is the x co-ordinate in pixels to be mapped to the image grid co-ordinate system, grid_spacing for the first DBS arrangement is the spacing between grid intersection points in pixels, Y_{image}_{_{—}}_{grid} is the y co-ordinate in the image grid co-ordinate system, and Yₚᵢₓₑₗ is is the x co-ordinate in pixels to be mapped to the image grid co-ordinate system.

FIG. 16 shows an ROI with pixel co-ordinates 1601 and 1604 defining the location of the ROI, and the corresponding image grid co-ordinates 1600 and 1603 respectively, which have been calculated using the above formula.

Each pair of points (X_{left}, Yₜₒₚ) 1601 and (X_{right}, Y_{bottom}) 1604 generated by an associated user input, defines one of the ROI 1605 within the image grid 1602 defined by the bounding image grid coordinates (X_{left}_{_{—}}_{image}, Yₜₒₚ_{_{—}}_{image}) 1600 and (X_{right}_{_{—}}_{image}, Y_{bottom}_{_{—}}_{image}) 1603. Each of these two-dimensional ROI are extracted and stored for use in a following step 1406 (see FIG. 14) in the memory 106. The bounding image grid co-ordinates are also stored for use. These extracted regions will be referred to herein as image grid sections, and each have dimensions section_w (ie 1606) and section_h (ie 1607), where section_w and section_h may be different. for each image grid section.

Returning to FIG. 14, in the following step 1406 each of the two-dimensional image grid sections are distributed across an image data grid for encoding in the protection dots of the document in later steps. This is achieved by first unwrapping each image grid section into a one-dimensional array of length section_w*section_h. The manner in which the two-dimensional image grid sections are unwrapped may be chosen to suit the particular DBS arrangement, however a raster unwrapping method is used in the first DBS arrangement. The unwrapped arrays are then concatenated into a single array, the image data tile, with a length of image data tile length equal to the number of value entries contained in all of the image grid sections.

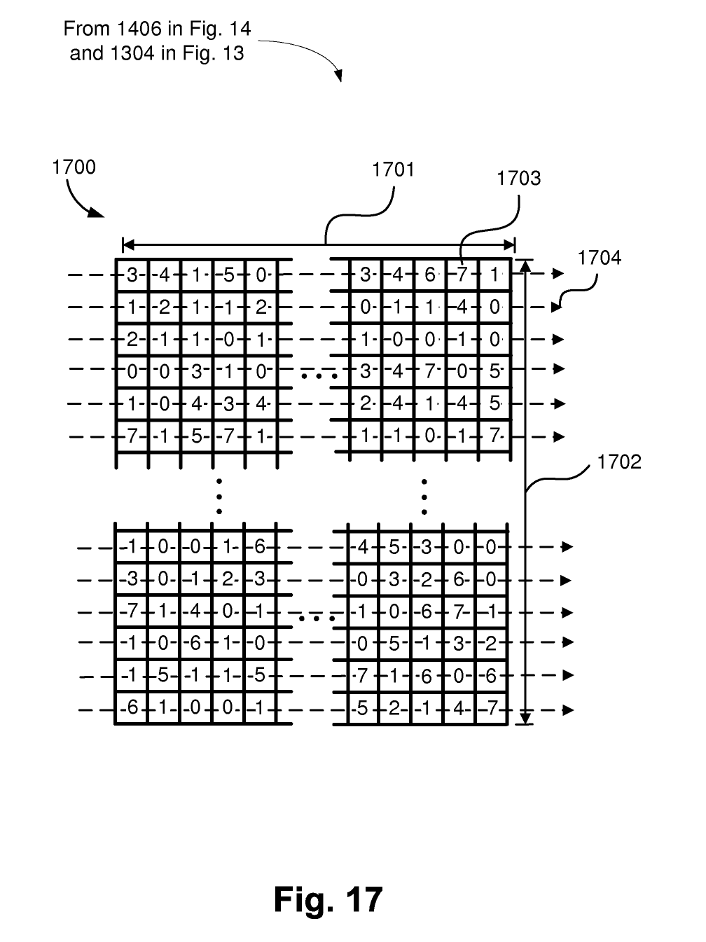

FIG. 17 depicts how the image data grid of dimensions image_data_grid_w (ie 1701) by image_data_grid_h (ie 1702) is then generated, where image_data_grid_w is the width of the image data grid, and image_data_grid_h is is the height of the image data grid.

The parameter image_data_grid_w is equal to align_grid_w and image_data_grid_h is equal to align_grid_h where align_grid_x is defined in [2], and align_grid_y is defined in [3]

The image data grid is then populated by repeatedly tiling the image data tile across the image data grid. Any suitable tiling method may be employed where each value in the image data tile appears roughly the same number of times. For the first DBS arrangement we use the following method. First assign in raster scan order a one-dimensional index to each of the points in the image data grid. Values are then added to the image data grid from the image data tile using the following formula:

Image_data_grid(i)=image_data_tile (i mod image_data_tile_size) [7]

where n mod m is modulus n of m.

Values are added until the image data grid is fully populated. A two-dimensional section of the image data grid is assigned as the values for the image data set of the protection dots, and hence the two-dimensional section of the image data grid forms the representation of the ROIs that will be available on decoding. It is preferable to avoid situations where the values from one image grid section, or some of the values from one image grid section, have a stronger representation than others. This is likely to occur in situations where the regular foreground features (text etc.) on a document have the same periodicity as the reference pattern. It is also preferable that the effects of burst noise be distributed throughout the ROI, i.e. that the relative location of protection dots is decorrelated with the relative locations of the areas they encode.

Therefore, given a single grid cell in the image data grid, it should be equiprobable that any of the values from the image data tile are present in an adjacent cell of the image data grid. Both of these requirements can be fulfilled by shuffling the image data grid using some suitable shuffling method which will be known to those skilled in the art. In the first DBS arrangement, a standard Knuth shuffle is employed by treating the image data grid as a one-dimensional array, however any other suitable shuffling algorithm can be employed.

Returning to FIG. 14 the process then proceeds to a step 1409, where values from the image data grid are associated with protection dots in the image data set. A process similar to that in the step 1002 (see FIG. 10) can be used to map image data set protection dots to values in the image data grid. Having regard to FIG. 12, the protection dot grid is offset into the image data grid by offsets x_grid_offset_{image} 1201 (which is equal to x_grid_offset 1201) and y_grid_offset_{image} 1202 (which is equal to y_grid_offset 1202). In such a manner, each point in the protection dot grid at grid co-ordinates 1203 (grid_x, grid_y) is associated with an image data value at image data grid co-ordinates 1204 (grid_x+x_grid_offset, grid_y+y_grid_offset) and hence is also associated with an absolute co-ordinate which is equal to the image data grid co-ordinate 1204. By using the shuffling methods proposed earlier there will be roughly an equal number of protection dots in the image data set representing each point in the image data tile. The process 1400 then ends with a terminate step 1408 and returns to the process 700 in FIG. 7.

### Associating Auxiliary Data

Returning to FIG. 7, in a subsequent step 705 auxiliary data is associated with the protection dots of the co-ordinate set. This step takes advantage of the fact that if a series of suitably small values (small in magnitude when compared to the maximum possible values stored in the protection dots) are added to the values from the co-ordinate set, the pattern of the co-ordinate set is still detectable. For example, if a value of either 0 or 1 is chosen at random and with equal probability for each grid cell in the alignment grid and added to that value, the altered alignment grid still strongly correlates with the original alignment grid as the average increase in error is small. The purpose of this auxiliary data is to store information about the location and type of ROI.

As described earlier, the DBS arrangements protect specific regions of the document having importance. In order to enable these ROI to be selected and encoded in a flexible fashion, and for the security document to be self-contained, the information about the location of these ROI is encoded in some of the protection dots on the security document. As the entire image data set of the security document is typically used for encoding the image content inside the ROI, it is preferable to store information about the ROI locations in the co-ordinate set. The first DBS arrangement encodes ROI locations in the co-ordinate set for the sake of greater self-containment of the features encoded on the security document. Alternatively, the auxiliary data may be encoded in an additional channel, or may share the image data set with the image data. The auxiliary data is associated with co-ordinate set in the first DBS arrangement as this presents a considerable saving in storage space used.

The step 705 is further detailed in FIG. 13.

FIG. 13 depicts how the process commences at a step 1300 and in a subsequent step 1301 a header structure is filled out. This structure contains information about the location and dimensions of the ROI's in image data grid co-ordinates within the absolute co-ordinate system established on the page in question. This information was generated in the step 1405 in FIG. 14. The header structure may also contain additional information about the ROI, as will be outlined in further DBS arrangements.

In a subsequent step 1302 the header structure is converted to a header binary representation of length L_{hbr} for use in a subsequent step 1303. A suitable checksum may be added to the end of the header binary representation. A data grid is generated in the following step 1303, with dimensions data_grid_h (ie 1106) and data_grid_w (ie 1105). These dimensions are equal to align_grid_x and align_grid_y respectively (ie 1101 and 1102 in FIG. 11).

The header binary representation is then tiled across the data grid, with one binary digit per cell in the data grid. Any tiling method is suitable as long as it is reproducible on the decoding side. For this arrangement we use the following method. First assign in raster scan order a one-dimensional index i to each of the points in the data grid. Values are then assigned using the following relationship:

data_grid(x,y)=header_binary_representation(L_{hbr} mod (x+y×data_grid_w)) [8]

where data_grid(i) is the i^{th} entry in the data grid, header_binary_representation is an array of binary values corresponding to the header data, L_{hbr} is the length of the header binary representation, mod is the modulus operation, x is the x co-ordinate within the data grid, y is the y co-ordinate within the data grid, and data_grid_w is the width of the data grid as defined earlier.

Every K_{length}_{_{—}}_{bit}_{_{—}}_{frequency}^{th} cell is used to encode the length of the header binary representation. The length of the header binary representation is calculated as an integer, and then converted to a binary length representation. Every K_{length}_{_{—}}_{bit}_{_{—}}_{frequency}^{th} cell in the data grid is replaced with a bit from the binary length representation in some fashion which is known both to the encoding process and the decoding process.

In a following step 1304, in a similar fashion to the step 1002 (see FIG. 10), the protection dot grid is offset into the data grid by offsets x_grid_offset 1201 and y_grid_offset 1202 (see FIG. 12). In such a manner, each point in the protection dot grid at grid co-ordinates 1203 (grid_x, grid_y) is associated with data grid cell at co-ordinates 1204 (grid_x+x_grid_offset, grid_y+y_grid_offset). Each dot in the grid will then have either a ‘0’ or ‘1’ associated with it.

Returning to FIG. 13 the process then terminates at 1305 and returns to the main process 700.

### Modulate Protection Dots by Assigned Values

Returning to FIG. 7 in a following step 707 the dots in the protection dot grid are modulated by the values assigned to them. For co-ordinate set dots, the assigned values are constituted by the sum of their associated alignment grid value and their associated data grid value, taken modulo 8. For data set dots, the assigned values are constituted by the sum of their associated alignment grid value and their associated image data grid value, taken modulo 8. In the case where some other scheme than an 8 point modulation scheme is used, the modulo nl of the sums are taken, where nl is the number of modulation positions in the scheme.

FIG. 4 illustrates one example of modulation of the protection dots. A spatially modulated protection dot 402 lies close to or upon an intersection point 405 of a regular grid 401. The protection dot 402 is spatially modulated to one of eight possible positions such as 403. The set of possible modulation positions is depicted by a dashed outline 409. The spatial modulation, performed by translating a protection dot 402 in a lateral (ie 407) and transverse (ie 408) direction relative to a corresponding intersection point 405, encodes data in the modulated protection dot.

The grid 401 is regular in the sense that it is definable and machine detectable and forms a set of reference locations (ie intersection points 405) in regard to which spatial modulation may be imposed upon corresponding protection marks. As illustrated for the first DBS arrangement in the example of FIG. 4, eight possible positions 409 for each protection dot are arranged in a three by three modulation position array centred on the corresponding grid intersection point 405. The central modulation position 406 of the three by three (3×3) array of modulation positions 409 is located at the grid intersection point 405, and corresponds to a modulation of zero distance horizontally (ie 407) and zero distance vertically (ie 408). This position is reserved, in the present example, solely for grid alignment dots. The remaining eight modulation positions are offset from the grid intersection point 405 horizontally, vertically, or both horizontally and vertically. Protection dots use these remaining modulation positions. While the first DBS arrangement uses a 3×3 array of modulation positions various other n×m arrangements may be employed.

The regular grid 401 may be conceptually viewed as a “carrier” signal for the modulated protection dots and, like a carrier wave in radio frequency communication, is not directly observable. The horizontal and vertical distance by which a modulation position is offset from the grid intersection point 405 is referred to as a modulation quantum 404, herein abbreviated as “mq”. The locations of the eight available modulation positions, relative to the corresponding grid intersection point 405, can be defined as a list of (x, y) vectors where x indicates the horizontal direction (407) and y indicates the vertical direction (408). Using the convention that rightward offsets (407) are positive with respect to x and downward offsets (ie opposite to 408) are positive with respect to y. The vectors are represented by the following set [9] of parameter pairs:

(−mq, −mq),

(0, −mq),

(+mq, −mq),

(−mq, +0),

(+mq, +0),

(−mq, +mq),

(0, +mq),

(+mq, +mq) [9]

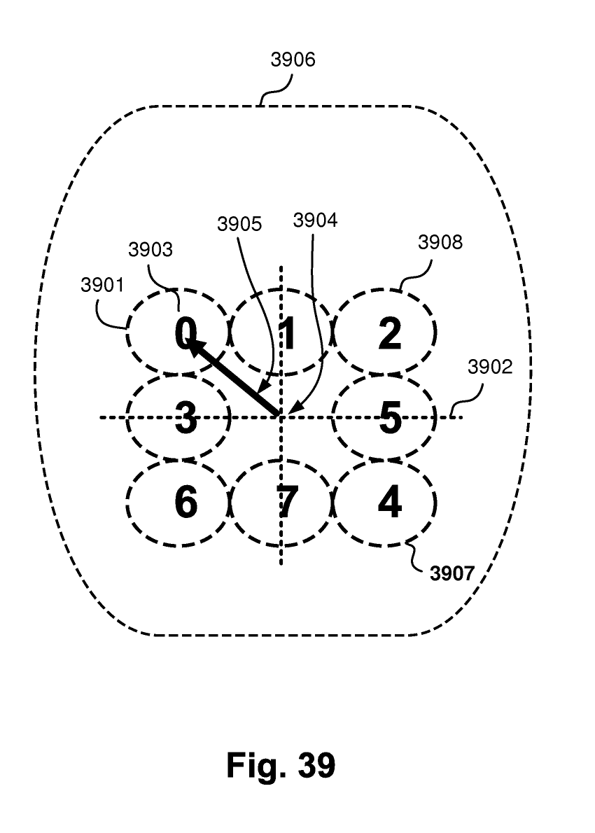

FIG. 39 shows dot modulation positions as depicted in of FIG. 4 in more detail. In FIG. 39, the set of modulation positions 3906 is centred on a grid intersection point 3904 of a grid 3902. Each modulation position, such as position 3901, has an associated digital code value 3903. The digital code value 3903 for the position 3901 is “0”. The eight modulation positions (including the modulation position 3901) allow each protection dot to encode one of eight possible digital code values (including the value 3903 for the position 3901). Each modulation position may equivalently be represented as a vector 3905.

The above described arrangement uses a base-eight modulation scheme with a three by three (3×3) array of modulation positions. Alternate modulation schemes with a smaller or larger number of modulation positions can be used. These alternate schemes can include base-4 (2×2), base-16 (4×4), base-25 (5×5), base-36 (6×6), base-49 (7×7), and so on. Modulation schemes based upon rectangular grids can also be used. For example, base-6 (2×3), base-12 (3×4), base-20 (4×5), base-30 (5×6), and base-42 (6×7) may be used if desired. Modulation schemes of other shapes (e.g. circular) can also be used.

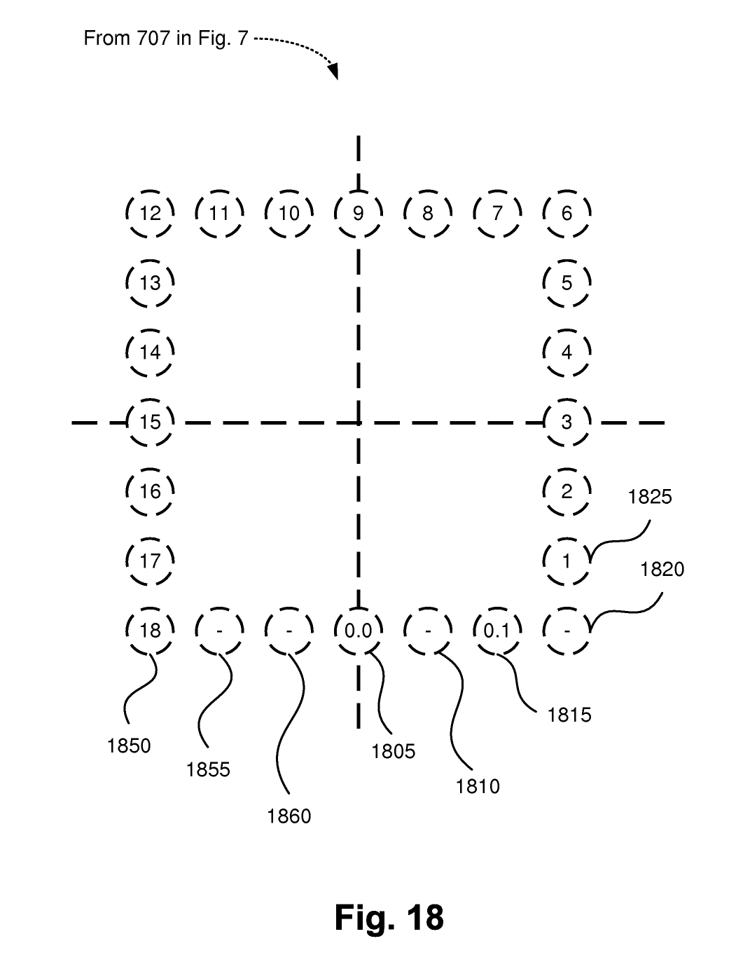

FIG. 18 shows another alternative where a base 19 system is used to encode data. In this arrangement 1805 and 1815 are both used to encode a value of zero. The values one 1825 to eighteen 1850 are encoded in an anticlockwise direction. The distance between some encoded values, such as zero 1805 and eighteen 1850, can be increased by not assigning values to positions 1855 and 1860. Similarly no value is assigned to positions 1810 and 1820.

Returning to FIG. 7, after performance of the step 707 the process is directed to a stop step 708.

### Verifying Security Documents

The purpose of encoding a document as described in the section Generating security documents is so that when the security document (referred to in the present context as a “received protected document”) is scanned by the scanner 126, a verification process can be performed, typically by operating in some manner upon the extracted security attribute(s), which validates the originality, prohibits further reproduction, provides evidence of tampering of the security document or some other security function.

FIG. 19 is a flow diagram showing a method 1900 for verifying (ie decoding) a received security document using a decoder apparatus implementing a DBS arrangement. The method 1900 is desirably performed by the DBS software application 133 executing on the PC 101 having input the received security document via the scanner 126.

### Extract Dot Values and Protection Dot Grid

The process 1900 begins with a step 1901, and proceeds to a step 1902 where a digital greyscale scan of the received security document is performed to detect dots and recover the values encoded in them. This process is further detailed in FIG. 20.

FIG. 20 depicts how the process 2000 begins at a step 2001 and proceeds to a following step 2002. Heuristics are used to locate all dots that appear like low visibility barcode dots in the scanned image derived from the received protected document. Due to the fact that dots are printed using normal colour printing processes, they may be detected using conventional image processing techniques. Dots printed using specialised printing processes may be detected by using appropriate methods that are known in the art. The output of 2002 is a list of (x, y) pixel coordinates of the centre of mass of each located protection dot.

In a following step 2003, a priority-based flood-fill algorithm is used to fit suitable grids over the locations of dots located in the step 2002. Alignment dots are used to aid in the detection of the grid. In the typical case the output of the step 2003 is a single grid that covers the entire scanned image of the received protected document. In some cases, multiple grids of different spacing and orientation covering the scanned image are identified. For example, if the scanned image contains two or more barcodes that are disjoint, have different spacing or different orientations, a separate grid will be associated with each barcode detected.

With the information extracted in 2003, the values encoded in each protection dot can be extracted into a two-dimensional array, preserving relative positions. In the first DBS arrangement, each grid cell has an interval associated with it which is a 3 bit value associated with the position of the protection dot as offset from the centre of the grid cell's intersection (ie the grid intersection point). The value or interval is extracted using the modulation scheme in FIG. 39.

The process 2000 terminates at a following step 2004 and returns to the process 1900 in FIG. 19

### Identify Reference Pattern

Returning to FIG. 19, the process 1900 proceeds to a step 1905 where the reference pattern described in the encoding section is detected from the values extracted in the step 2003 (see FIG. 20). As previously noted the reference pattern (eg see 802 in FIG. 8) establishes local context to assist in choosing which protection dots are in the co-ordinate set and which are in the image data set.

As an extension to the DBS arrangement, data may be encoded in this reference pattern and hence extracted in this present step 1905.

### Extract Co-ordinate System Information

With the intervals of the protection dot grid established and the reference pattern identified in the step 1905, the co-ordinate set (and thus the absolute co-ordinate system) can be extracted in a following step 1903. As previously noted the co-ordinate set is a set of protection dots whose members encode a series of pseudo random values which are used to establish an absolute co-ordinate system over the grid cells of the page 310 (see FIG. 3), and also encodes a second auxiliary data channel which contains information about the location and types of ROI on the document.

The step 1903 extracts the co-ordinate set into a two dimensional alignment value array, reconstructs the original alignment grid and correlates the alignment value array with the alignment grid to thereby determine the offset of the protection dot grid on the page in relation to the absolute co-ordinate system. This is further detailed in the process 2400 in FIG. 24.

With the reference pattern identified, the co-ordinate set is extracted as per the pattern defined in FIG. 8, which was used during encoding. FIG. 8 shows how each value in a co-ordinate cell 805 is identified as a co-ordinate grid value, taking note of its logical co-ordinates, which are an arbitrarily defined two-dimensional co-ordinate system which represents the relative positions of each cell in the protection dot grid.

FIG. 24 is a flow diagram showing a process 2400 for establishing the absolute co-ordinates of the protection dot grid. The process 2400 commences with a step 2401 and then in the following steps 2402 and 2403, the co-ordinate grid values are mapped into the co-ordinate grid value array based on their logical co-ordinates. The alignment grid values extracted from the protection dot grid position in the step 2402 at (X_{logical}, Y_{logical})=(Xₘᵢₙ_{_{—}}_{logical}_{_{—}}ᵥₐₗᵤₑ, Yₘᵢₙ_{_{—}}_{logical}_{_{—}}ᵥₐₗᵤₑ), i.e. the value with the smallest logical co-ordinates maps to (Xᵥₐₗᵤₑ_{_{—}}_{array}, Yᵥₐₗᵤₑ_{_{—}}_{array})=(0,0). Xₘᵢₙ_{_{—}}_{logical}_{_{—}}_{value and Y}ₘᵢₙ_{_{—}}_{logical}_{_{—}}ᵥₐₗᵤₑ may be derived from different logical co-ordinates. Each subsequent value is mapped in the step 2403 to the alignment value array position (Xᵥₐₗᵤₑ_{_{—}}_{array}, Yᵥₐₗᵤₑ_{_{—}}_{array})=(X_{logical}−Xₘᵢₙ_{_{—}}_{logical}_{_{—}}ᵥₐₗᵤₑ, Y_{logical}−Yₘᵢₙ_{_{—}}_{logical}_{_{—}}ᵥₐₗᵤₑ). In a following step, 2404, the alignment value array is correlated with the reconstructed alignment grid. The alignment grid is constructed in the same fashion as in the encoding side of the algorithm, using an identical seed which is mutually available to both the encoding process and the decoding process in a system that encodes and decodes a document. Provided that a suitable number of protection dots are decoded and a suitable number of alignment values are present, the correlation will produce a single strong correlation peak at the point where the value array is displaced by the values (X_{displacement}, Y_{displacement}), measured in grid cells.

Using these values, it is then possible to map each grid cell in the grid to a cell in the alignment grid, and hence assign each grid cell in the grid an absolute co-ordinate (i.e. the alignment grid co-ordinates).

Alternatively, in the aforementioned case where the reference pattern is not encoded in the protection dots, the entire set of values extracted in the step 2003 (see FIG. 20) may be placed in the co-ordinate grid value array and correlated with the alignment grid. This will mean that image data values will be present in the co-ordinate grid value array. However, these values will essentially equate to random noise as they have been shuffled by random values, and as a result only have a small impact on correlation strengths provided sufficient co-ordinate grid values are present.

As a simple extension to the DBS arrangement, rotation of the document that is greater than +/−45 degrees from the normal can be compensated for. When the document is scanned at greater than +/−45 degrees, the protection dot grid logical co-ordinate system may be established in a direction n×90 degrees to the normal (where n is an integer) compared to the co-ordinate system which was established on the encoding side. In the case where n is not equal to 0, the correlation will fail. A solution is to perform four correlations, with the jth correlation using a page grid rotated at j×90 degrees. When the correlation peak is found, a rotational correction, as well as a displacement correction can be applied when mapping the logical co-ordinates to the absolute co-ordinate system.

The process 2400 terminates at 2405, returns to the process 1900 in FIG. 19.

### Recover Unshuffled Values

The purpose of aligning the logical grid with the alignment grid is two-fold. As already mentioned, it serves the purpose of establishing an absolute co-ordinate system over the protection dot grid which, given the pixel co-ordinates of the protection dots on the document, can be used to infer the pixel co-ordinates of region on the document, without any reference to external data sources. Furthermore, as each value in a grid cell has been modulated by its associated random value in the alignment grid so to add security and make the grid harder to visually observe, it is necessary to determine which random value each dot was modulated by so that the original value can be retrieved. This is performed in step 1907 in FIG. 19.

As the relationship between the grid cells and the alignment grid cells has been established, it is a simple task to convert the assigned value of each grid cell, which was extracted in step 1902 to its original encoded value by adding 8 to the assigned value of the grid cell (or in extensions where some other modulation scheme is used, the maximum possible value of an assigned value of the grid cell plus 1), subtracting the associated random value and then taking the modulus 8 (or in extensions where some other modulation scheme is used, the maximum value of a grid cell value plus 1) of the is resultant value. This will return the demodulated grid.

### Extracting Auxiliary Data

In a following step 1909, the headers encoding information about the locations and types of ROI in the document are decoded. As described in the encoding side of the DBS arrangement, header information is encoded in an auxiliary data format in the co-ordinate set. As the co-ordinate set grid cells have now been demodulated by the random values from the alignment grid, the values at the locations designated as alignment grid cells in the demodulated grid will now contain a series of 0's and 1's corresponding to fragments of the original data contained in the data grid in the encoding phase. The relationship between the logical grid and the absolute co-ordinate system has been established in step 1903. Using this relationship, the binary data values are mapped to the reconstructed data grid. The reconstructed data grid is of dimensions align_grid_w by align_grid_h i.e. identical in dimension to the alignment grid. The length of the repeated data pattern can be extracted by sampling the bits every K_{length}_{_{—}}_{bit}_{_{—}}_{frequency} dots and reconstructing the data pattern length information. The repeated data pattern can then be aggregated and recovered. The aggregated data can then be parsed into header data and the absolute co-ordinates and types of ROIs can be established.

As explained earlier, header data may alternatively be stored in an additional set of dots or may share the image data set with image data. It may also be split between multiple sets of dots. A suitable encoding scheme may be decided in the encoding step and the corresponding decoding step may be performed instead of the methods outlined in this section.

### Extract Image Data Information

In a subsequent step 1908 the image data values are extracted from the demodulated grid. The process is further described in relation to FIG. 26. The process 2600 begins at a step 2601 and proceeds to a step 2602 where the protection dots of the image data set are extracted from the protection dot grid. In the step 2402 (in FIG. 24), the co-ordinate set was extracted into a temporary 2D array. In this present step 2602, the remaining protection dots (the image data set) are extracted taking note of their location in the absolute co-ordinate system. In a following step 2603, the values are placed in an image data grid of identical proportions to the original image data grid in the encoding description. In a subsequent step 2604 the image data tile length is calculated from the header information extracted in the step 1909, and the image data tile is recovered by aggregating the values in the image data grid. In a following step 2605, the image data tile is broken up firstly into sections of 1D image grid sections, each of which are then restructured into two-dimensional image grid sections based on header information. The process 2600 then finishes at a step 2606 and returns to the process 1900 in FIG. 19.

With the two-dimensional image grid sections extracted, image information about the expected attributes of the content in the ROI, the location of each ROI in the absolute co-ordinates system and the type of ROI area are all available for the next step of processing.

A next step 1906 determines the average pixel intensity in an area (eg 1502 in FIG. 15) surrounding each grid intersection point within the ROI. Before determining the average pixel intensity the scanned greyscale image is binarised to form a black and white image. First a filter function, such as a Gaussian blur, is applied to the greyscale image. Next the greyscale image is binarised, by applying a threshold function, to form a black and white image. This is the same process that is applied during the encoding process and is used to increase the similarity between the encoded image and the decoded image. The image binarization process also removes the protection dots that were added during the encoding process.

In FIG. 27 the character ‘E’ (1503 From FIG. 15) has been tampered with to form an ‘8’ as depicted by a reference numeral 2701. The tampered region is highlighted by a cross hatched area 2702. In FIG. 15 the average pixel intensity of the area 1502 around the grid intersection 1501 is measured.

Returning to FIG. 19 the image data value for each cell in the two-dimensional image grid sections extracted in the step 1908 can then be compared to each corresponding average pixel intensity measured in the step 1906. However, the received security document may have undergone some processing (such as printing and scanning) which would give a systematic error for all the grid intersections. To overcome this, automatic calibration is performed as a preliminary part of a following step 1911. For each possible image data value (0-7 in the example described), every grid intersection with that image data value is examined, and the mean of their measured average pixel intensity is calculated. A calibration map can be constructed from the image data values and the means calculated. The calibration map thus constructed provides a mapping from each image data value to a measured average pixel intensity. It is possible to use other statistical means to calculate the calibration map; for example by using the median values, or by plotting the values on a graph and using a line of best fit.

### Generate Tampering Information

Document tampering is then detected. At each grid intersection point which falls within an ROI, the corresponding image data value in the two-dimensional image grid sections is mapped to an expected value using the calibration map constructed in the step 1911. The difference is found between the image data value and the actual value measured in the step 1906, giving an error at each grid intersection point within an ROI.

A tamper image which is a greyscale bitmap image of the same size as the security document is created in the step 1911 to represent the tampering, with all pixels initialized to 0. Pixels in the tamper image corresponding to each grid intersection point within an ROI on the security document are set to the error calculated for those intersections. A filter function (e.g. gaussian blur) is applied to the tamper image so that the pixels containing errors are spread into their local areas. Preferably this filter function is a similar shape and size to the area 1502 (see FIG. 15) used while encoding the document.

At this stage the tamper image has areas of 0 intensity representing (a) untampered areas or areas which are not within an ROI, (b) areas which have negative values representing areas where content has been deleted, and (c) areas with positive values representing areas where content (such as handwritten text or tampering) has been added. By choosing a threshold value greater than 0, and setting all pixels below this to a threshold representing white, and all pixels above this threshold to a value representing black, the tamper image will clearly display areas where content has been added. It is possible to superimpose the tamper image onto the protected content, ideally converted to a conspicuous colour. An example result is shown in FIG. 27, with the tampered region 2702 highlighted.

In a similar way, a negative threshold can be chosen, all pixels below this threshold set to a value representing black, and all pixels above this threshold set to a value representing white. The tamper image will then clearly display areas where content has been deleted. This tamper image can also be superimposed onto the security document, ideally converted to a conspicuous colour.

Continuing step 1911, a missing dots image representing tampering is created by finding all the grid intersections where a dot could not be found or decoded. A greyscale bitmap image is created of the same size as the security document where all the pixels are initialized to 0. Pixels corresponding to the grid intersections where dots are missing are set to a value higher than 0. Because it is expected that more dots will be missing in areas of high average pixel intensity (e.g. around text), the aforementioned value should be inversely proportional to the average pixel intensity. Next, a filter function (e.g. Gaussian blur) is applied to the missing dots image. A threshold is chosen, and all pixels above this threshold are set to a value representing black, and all pixels below this threshold are set to a value representing white. The missing dots image can also be superimposed onto the security document, ideally converted to a conspicuous colour.

Ideally the aforementioned positive, negative & missing dots thresholds should be chosen interactively, e.g. by movable sliders on a graphical user interface. Modifying the values of the thresholds changes the sensitivity of the detection process.

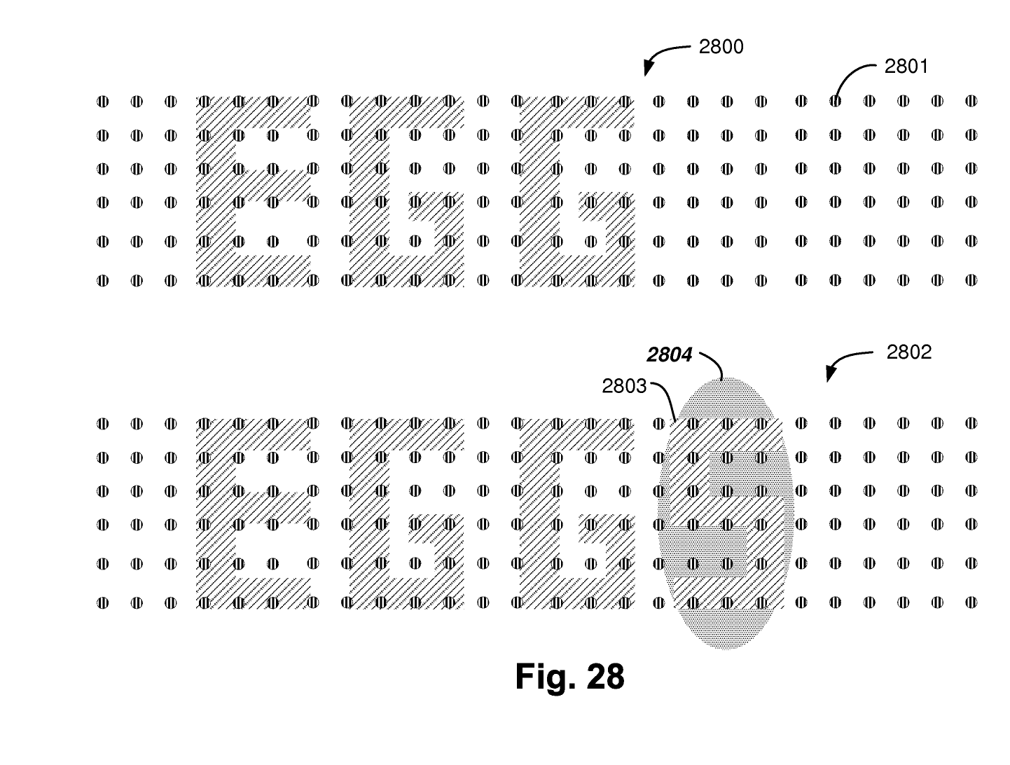

FIG. 28 depicts a security document, which has been altered in an unauthorised manner, after being processed according to the previously described methods. A first view 2800 shows a fragment of a security document upon which the word “EGG” and an associated array 2801 of protection dots has been printed. A second view 2802 shows the same document fragment after being processed according to the previously described methods. In the second view, the word “EGG” has been amended, in an unauthorised manner, to read “EGGS”. The unauthorised amendment (ie tampering) comprising the added letter “S” (ie 2803) is clearly indicated by a highlighted area 2804 produced by the previously described methods.

It is worth noting here that a number of the preceding steps can be performed together to avoid multiple iterations over the grid, but are explained in a stepwise fashion here for ease of understanding.

### Second Arrangement

In a second arrangement of the DBS arrangement, the features described in the first arrangement are adapted to extract handwritten additions to a security document, referred to herein as a workflow document for the sake of disambiguation.

In addition to security applications, self contained features such as those described in the first arrangement may be useful in creating a workflow document which can provide information to a user about where (ie which stage in a predefined workflow) handwritten additions have been made to a document. This may in turn be used to facilitate workflow applications such as automatic processing of examination papers, application forms and other types of documents that receive handwritten input.

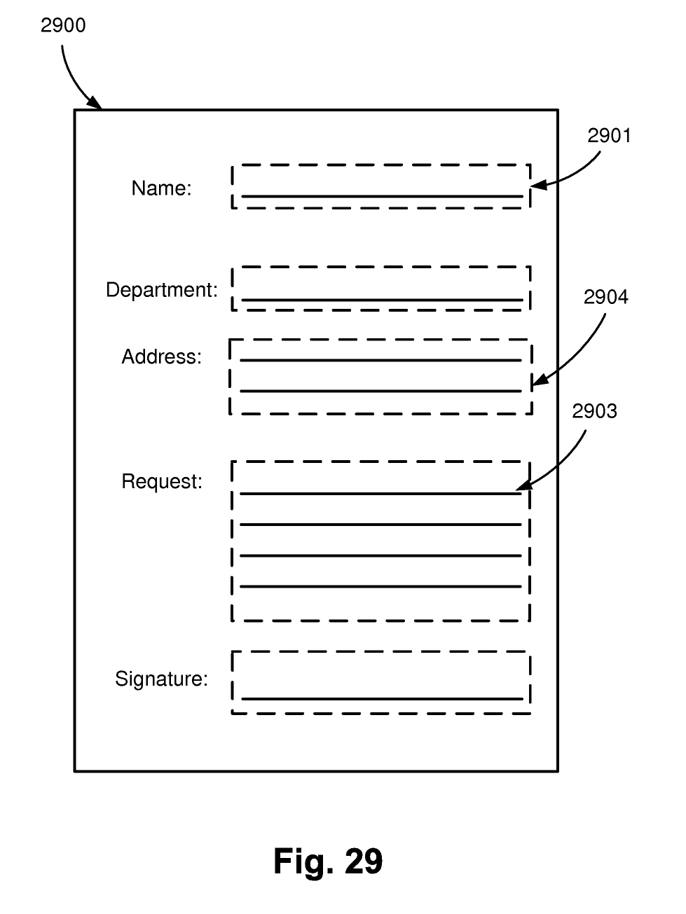

FIG. 29 depicts a typical layout for a workflow document. Each workflow document 2900 has a number of regions 2901 where handwritten input is expected. Additionally, each region may have region information associated with it (similar to XML mark-up), identifying such things as the type of region e.g. a ‘Name’ field on an internal request form, or possible properties of the expected input i.e. the input text will be numeric, or text will be blue etc. This region information typically has numerous uses, ranging from aiding an Optical Character Recognition (OCR herein) system in recognizing handwritten characters to providing cues for a document workflow to process the handwritten input. The security attributes of the regions encoded in the features of the workflow document are typically used to identify changes to the document in these regions. However, unlike the first arrangement, where a high detection probability is crucial, the attributes encoded are specifically selected to favour higher resolution detection of changes rather than high detection rates (there is generally a trade off between the two). That is, the features encoded will include higher resolution information about the document contents, with less redundancy. This is particularly useful in cases where there is pre-existing foreground (i.e. lines 2903) inside the regions and it is desirable for the system to be able to discern between written input and pre-existing foreground.

### Encoding Workflow Documents

The set of marks in the second arrangement take the same form as in the first arrangement, namely a low visibility barcode with the structure shown in FIG. 3 and described in the section entitled ‘Generating Security Documents’. Selection of ROI is performed in largely the same fashion as used in the first arrangement. However, as the generation of workflow documents is geared towards processing of a large number of identical documents, it may be more common in the case of a workflow documents to identify the location of the ROI using a computer interface such as the mouse 101, and then re-use these ROI as a template when generating multiple identical workflow documents.

The process for encoding a workflow document is similar to that described in the first arrangement 700. The process 700 proceeds as in the first arrangement for the steps 701, 702, 703 and 704.

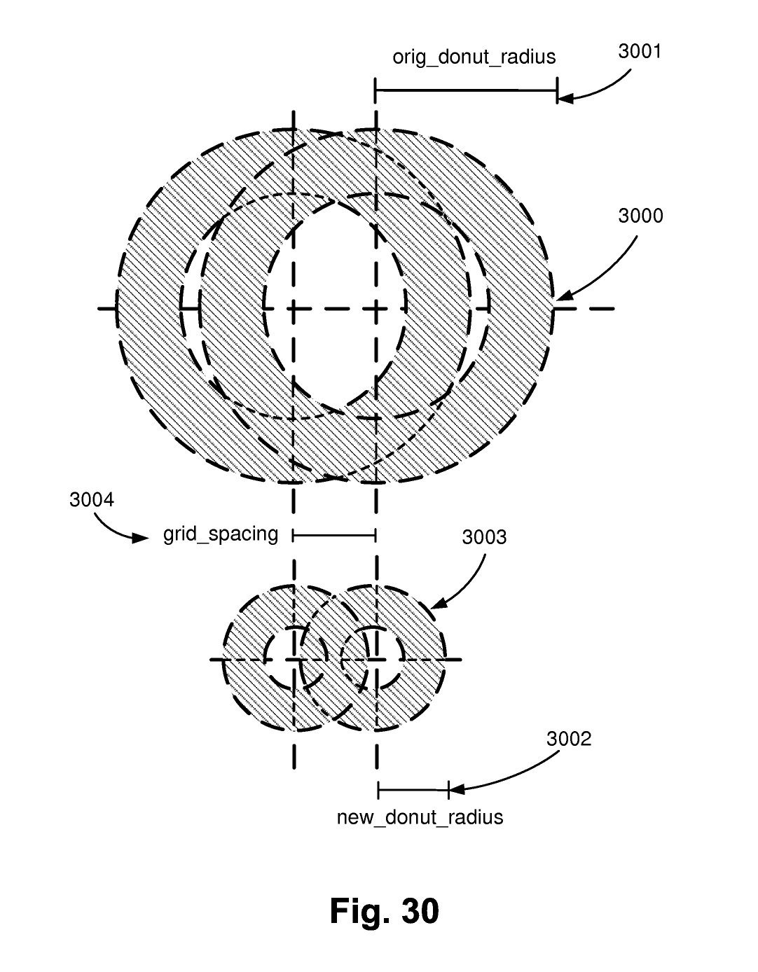

In regard to the step 706, the area 1502 (see FIG. 15) chosen for generating the average pixel intensity is altered to provide better resolution when detecting additions without decreasing the spacing between samples. This is performed by decreasing the radius of the area in 1502 (shown again in FIG. 30 as 3000), from orig_donut_radius 3001 (the value used in the first arrangement) to new_donut_radius 3002, creating the new area 3003. The two radii 3001 and 3002 may be 45 pixels and 20 pixels respectively, although values may be varied based on the desired resolution versus consistency of detection.

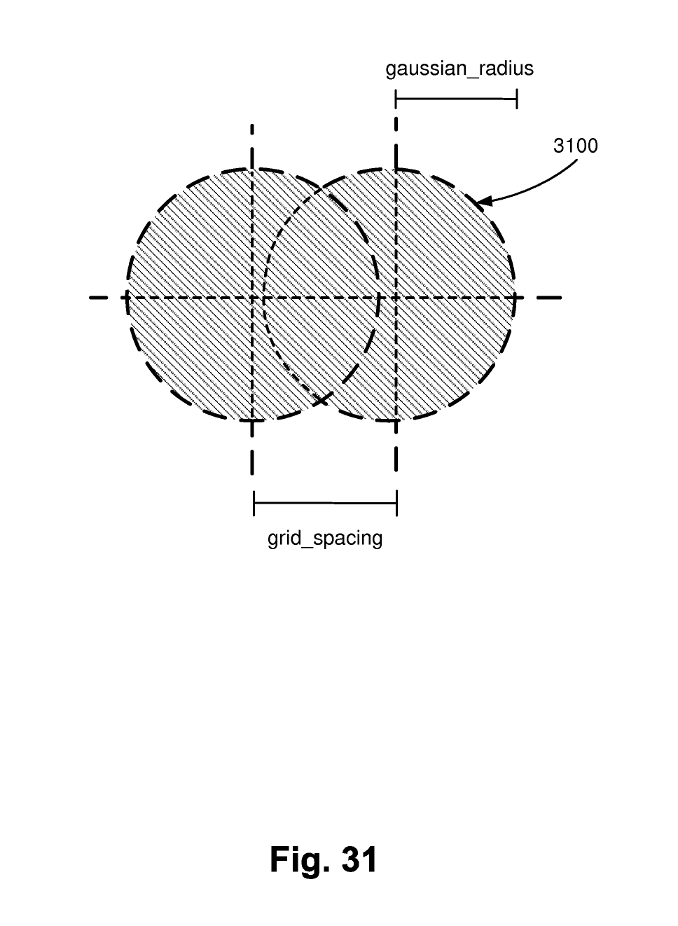

Larger radii mean that information about attributes of a certain point in a region is distributed over a larger number of dots and hence more likely to survive damage to the features. Conversely, resolving power is decreased. Smaller radii distribute the information over fewer dots (i.e. decrease the amount of overlap between areas) but have better resolving power. Both arrangements use the same grid spacing 3004. As an alternative, the area in which to calculate the average pixel intensity may be a simple circular area 3100 (see FIG. 31). As the radius of the annular area decreases the benefits of using the donut-shaped filter decrease and are at a certain point outweighed by the extra computational cost.

The step 706 is, after making the above-noted adjustments, then performed in the same fashion as in the first arrangement.

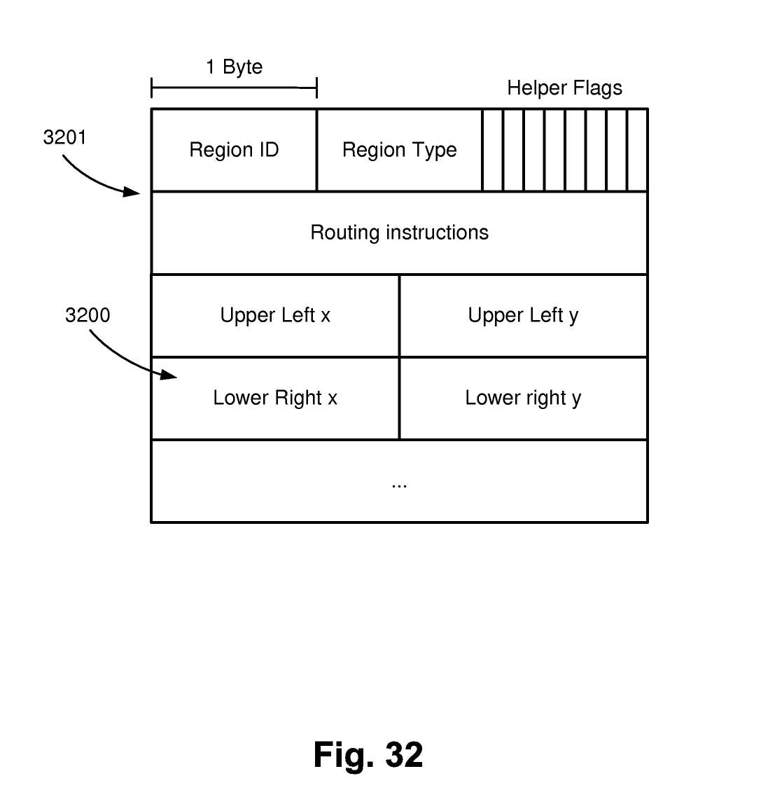

In relation to the subsequent step 705, in the sub-step 1301 (FIG. 13) the header structure is filled out not only to contain the corner co-ordinates of the rectangular regions, but also information about the type of region, likely input and instructions for processing may be included. A possible structure for a single region entry in the header is shown in FIG. 32. In addition to the fields 3200 which specify the shape and location of the region, there are a number of other fields 3201. These specify a UID for the region, a region type (i.e. a name field, an address, an answer to a question), a number of helper flags which may specify extra information for an OCR system such as the type of input expected in the region, the colour of pen used or otherwise, and routing instructions specifying where the processed output from this region is to be sent. The header may contain a main header for the entire document, containing a UID for the document as well as instructions for the processing of each region.

Alternatively, the region type field and routing instructions may be removed from the individual region headers and a single set of instructions for processing the page may be included in a master header.

This header is then encoded as per the steps 1302, 1303 and 1304 in the first arrangement and the step 704 is completed as in the first arrangement.

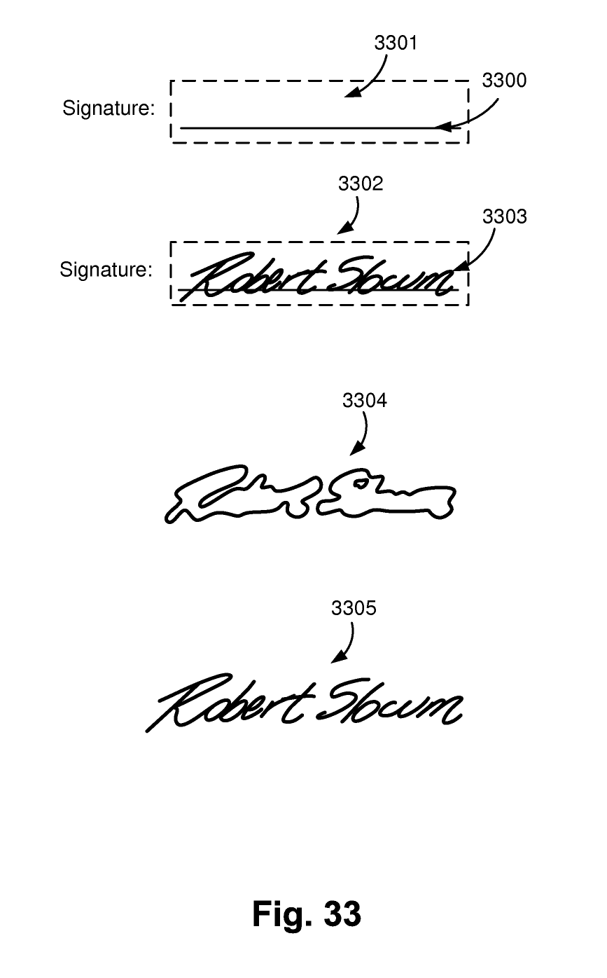

The remainder of the process 700 is completed as in the first arrangement. One possible extension to the DBS arrangement for the second arrangement is changing the quantization scheme used to map average pixel intensities to digital code values in the step 706. This takes advantage of the fact that there is no need to detect deletions of text for handwriting detection. As the main interest is in detecting additions to areas with pre-existing foreground text 3300 (see FIG. 33), (noting that additions on areas with no pre-existing foreground 3301 are trivial to detect), it is possible to improve performance by scaling the average pixel intensities to digital code values so as to assign more digital code values to encoding the darker part of the image intensity value dynamic range. This extension allows finer discernment of one dark area from another.

### Decoding Workflow Documents

The process 1900 is performed as described in the first arrangement for steps 1901 to 1903 In the step 1909, the new fields in the header data must also be extracted and stored for future use, possibly to be passed off to an OCR system which processes the extracted handwriting or to the workflow system which processes the output of the OCR system.

Step 1908 is completed as in the first arrangement.

Step 1909 employs the new method described in the section Encoding Workflow Documents for calculating average pixel intensities. This may either use the smaller donut 3003 (FIG. 30) or the circular area 3100 (FIG. 31), but must be consistent with the shape of the area used in the encoding step.

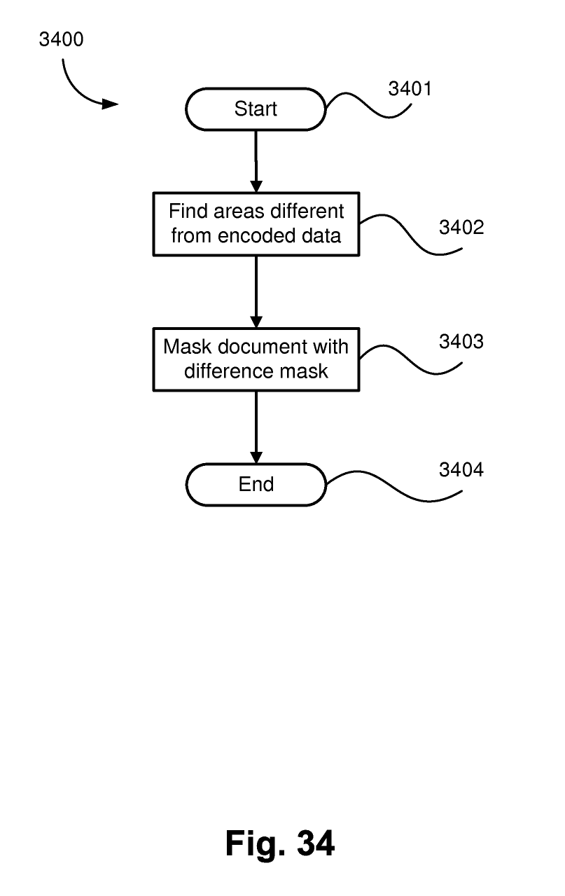

The second arrangement then bypasses the step 1911 and enters a new process 3400 depicted in FIG. 34.

FIG. 34 is a flow diagram showing a process for extracting handwritten text from a document. The process begins at a first step 3401 and proceeds to step 3402. Automatic calibration is performed as a preliminary part of the step 3402. For each possible image data value (0-7 in this case), every grid intersection with that image data value is examined, and the mean of their measured average pixel intensity is calculated. A calibration map can be constructed from the image data values and the means calculated. The calibration map thus constructed provides a mapping from each image data value to a measured average pixel intensity. It is possible to use other statistical means to calculate the calibration map; for example by using the median values, or by plotting the values on a graph and using a line of best fit.

At each grid intersection point which falls within an ROI, the corresponding image data value in the two-dimensional image grid section is mapped to an expected value using the calibration map. The difference is found between the image data value and the actual value measured in the step 1906, giving an difference at each grid intersection point within an ROI. A difference image which is a greyscale bitmap image of the same size as the workflow document is created to represent the changes to the document, with all pixels initialized to 0. Pixels in the difference image corresponding to each grid intersection point within an ROI on the workflow document are set to the difference calculated for those intersections. A filter function (e.g. gaussian blur) is applied to the difference image so that the pixels containing differences are spread into their local areas. Preferably this filter function is a similar shape and size to the area 3003 (FIG. 30) or the circular area 3100 (FIG. 31) used while encoding the document.

At this stage the difference image has areas of 0 intensity representing unchanged areas or areas which are not within a ROI and areas with positive values representing areas where content (such as handwritten text or tampering) has been added. No deletions are detected as they are not of interest in this arrangement. By choosing a threshold value greater than 0, and setting all pixels below this to a threshold representing white, and all pixels above this threshold to a value representing black, the thresholded difference image or difference mask 3304 (FIG. 33) will clearly display areas where content has been added.

As with the first arrangement, the threshold value may be chosen interactively by a user. It is suggested however that this threshold value is calculated automatically. One possible solution is empirical calculation of a global threshold value based on knowledge of the document type and print channel. Another is using a 2D averaging filter which is capable of identifying the difference between noisy areas of the difference image and actual differences 3303. The values for this filter could again be determined through experiment based on the expected document type and channel.

The process then proceeds to a step 3403 where the difference mask is used to mask out the added text 3303 from the workflow document 3302. This is effectively a Boolean AND (&&) operation between the two images. The added foreground areas within regions of the difference mask are taken as additions and output as the added text image 3305. The process then terminates at 3404 and returns to the main process 1900 in FIG. 19, which in turn terminates at 1912. The added text image may be output to an OCR system, possibly with the auxiliary information included in the header information of each ROI, and the header information included in the main header.

### Third Arrangement

In a third arrangement of the DBS approach, the security features are used to encode a security attribute corresponding to information about the security status of the regions of the security document (referred to herein as a secured access document for the sake of disambiguation). In this particular example, a system for redacting or ‘masking’ sensitive information will be described.

In addition to security applications, self-contained security features such as those described in the first arrangement may be useful in creating a secured access document. This document provides information to a user about (a) the type of regions present on a document, (b) who is allowed to access the information in these regions, and possibly (c) information about what actions to perform when certain users attempt to obtain their own copy of the secured access document from an original.

Each document 2900 (see FIG. 29) has a number of regions 2904 which contain sensitive information, or will have sensitive information input when the secured access document is filled out by a user. Each region has region information associated with it (similar to XML mark-up), identifying such things as the type of region e.g. an ‘Address’ field on an internal request form, or possible properties of the expected input i.e. the input text will be numeric, or text will be blue etc. The region information also has information about the security level of the region. One example is where a number of levels of security clearance are defined, and the minimum required security level clearance to view a region is encoded in the region information. A secured access document may also contain a combination of regions described in workflow documents and security documents to form a composite document, with all regions possibly sharing the same absolute co-ordinate system.

### Encoding Workflow Documents

The sets of marks in the third arrangement take the same form as in the first and second arrangements, namely a low visibility barcode with the structure shown in FIG. 3 and described in the section ‘Generating Security Documents’. Selection of ROI is performed in largely the same fashion as the first arrangement. However, as the generation of secured access documents is geared towards processing of a large number of identical documents, it may be more common in the case of a secured access document to identify the location of the ROI using a computer interface such as the mouse 101, and then re-use these ROI as a template when generating multiple identical secured access documents.

The process for encoding a secured access document is similar to that described in the first arrangement 700 (in FIG. 7). The process 700 proceeds as in the first arrangement for the steps 701 and 702.

The step 703 may be bypassed if the secured access document does not contain regions such as those described in regard to the secure document or workflow document, as there is no need to allocate dots to the image data set to encode image data. All protection dots may instead be used to encode the co-ordinate set. Alternatively, in place of, or along with the image data set, a header data set can be used to encode header information, instead of embedding the header information in the co-ordinate set. This is useful if a large number of secured access regions are to be encoded. In this case the size of the header data set is decided in a similar fashion to the first arrangement. If N_{cd} is the size of the co-ordinate set (in number of dots), and N_{hd} is the size of the header data set (also in number of dots), then for this arrangement K, being the dot membership ratio, is given by the following relationship:

K=N_{cd}−/N_{hd} [10]

A larger K is preferable for documents where there is likely to be a large amount of damage to the barcode (i.e. missing dots due to overprinted text) when the document is printed. A smaller K allows more regions to be identified but may result in the document failing to be decoded if there are not enough protection dots of the co-ordinate set identified to establish the co-ordinate system.

The step 704 then proceeds as in the first arrangement.

The step 706 may be bypassed if the secured access document does not contain regions such as those described in relation to the secure document or the workflow document. If it does contain either of these types of regions, the step is performed as in the corresponding arrangement.

In the step 705, in the sub-step 1301 the header structure is filled out as in the second arrangement, however an additional security field is added. Instructions for processing the region are also included in the header structure. For example, an instruction may indicate that a region is to be masked out (i.e. printed over in black or some appropriate colour when printed out) if a user with insufficient security privileges attempts to copy the document. The recording of the security level and instructions in the security features of the document are an important step in allowing the document to be processed without the need for a centralised information source.

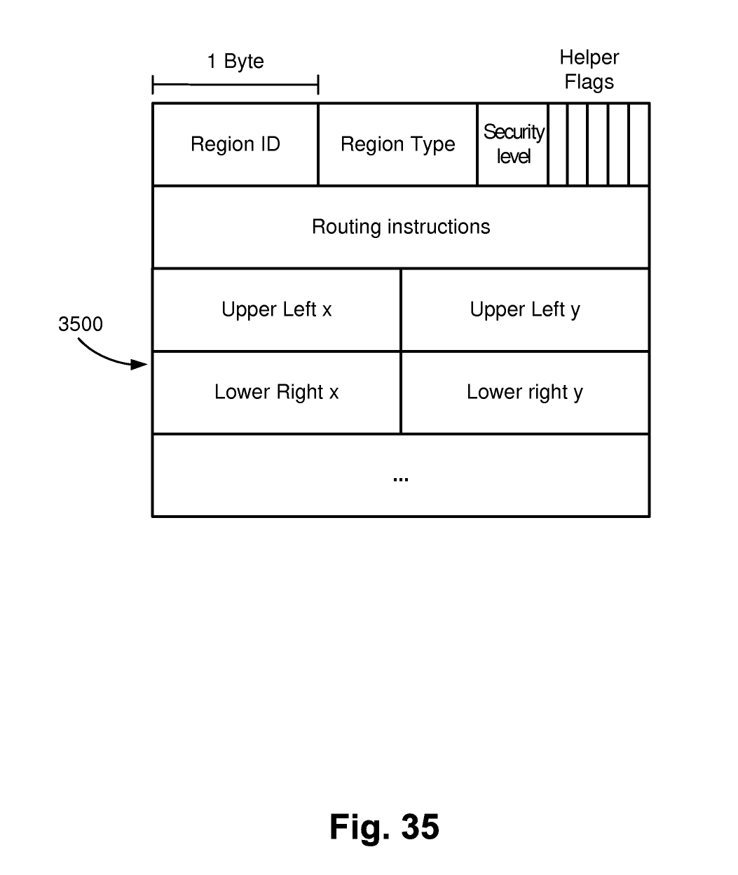

A possible structure for a single region entry in the header is shown in FIG. 35. As in the second arrangement, the header may contain a main header for the entire document, containing a UID for the document as well as instructions for the processing of each region.

Alternatively, the region type field and routing instructions may be removed from the individual region headers and a single set of instructions for processing the page may be included in a master header.

The steps 1302 and 1303 are performed as in the first arrangement. For the step 1304, if the image data set has been replaced or combined with a header data set, the data grid values may be assigned to the header data set. Otherwise, data grid values are assigned as in the first arrangement.

The remainder of the process 700 is completed as in the first arrangement.

### Decoding Secured Access Documents

The process 1900 is performed as described in the first arrangement for the steps 1901 to 1907. In the step 1909, the new fields in the header data must also be extracted and stored for future use. The header data is extracted from one of the header data set or the co-ordinate set where the header data was encoded.

If regions described in the first or second arrangement are present, the step 1908 is completed as in the first arrangement. Otherwise, this step is bypassed.

If regions described in the first or second arrangement are present, the step 1906 is performed according to the corresponding arrangement.

If regions described in the first or second arrangement are present, then the step 1911 is performed as in the corresponding arrangement. Otherwise, the second arrangement bypasses the step.

In addition, secured access operations may be performed in this arrangement provided that at least one secured access region is present.

As each secure access region has a security level and related processing instructions, it should be apparent to someone skilled in the art that a number of security applications are possible.

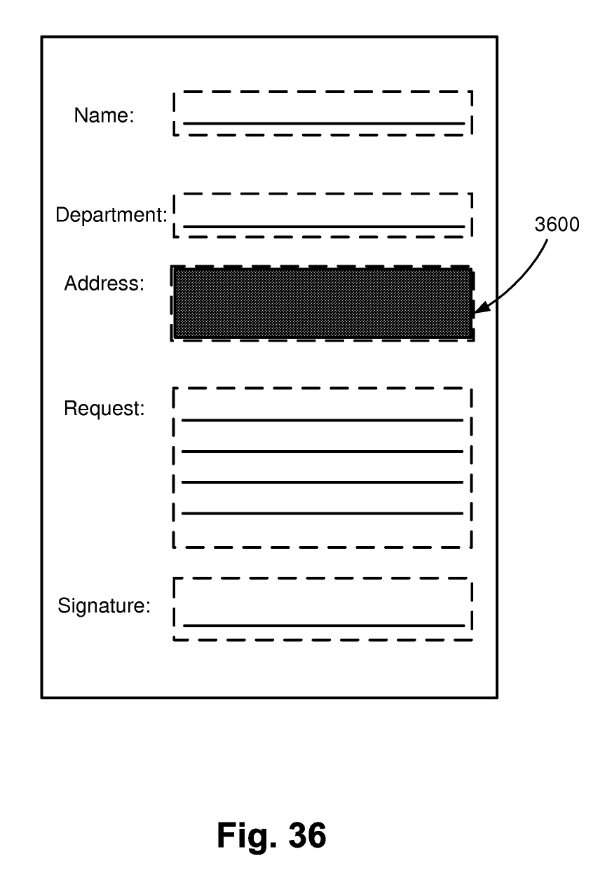

One example, and the focus of this arrangement, is the masking of secured access regions. A document may contain a number of secured access regions, with each region assigned one of a number, N_{sec}, of security levels. Any user attempting to copy or scan the document using a Multi-Function Printer (MFP) will be required to swipe in to the device using a Smart Card or some similar form of self-verification. The user's security clearance level may then be ascertained. If the user's security clearance level is less than that encoded in the header data for the secured access region, then the corresponding instructions encoded in the header data are carried out. In this example, the corresponding instruction would be to reproduce the document with the secured access region 3600 masked out as in FIG. 36 and only then to copy or scan the document. While this is one specific example of how the methods in this arrangement may be used, other functions such as requesting a password before reproducing the secured access region, limiting the list of users a user may scan and send the information contained in the secured access region to based on the security level, as well as various other applications are possible.

### INDUSTRIAL APPLICABILITY

The arrangements described are applicable to the computer and data processing industries and particularly for the document processing industry.

The foregoing describes only some embodiments of the present invention, and modifications and/or changes can be made thereto without departing from the scope and spirit of the invention, the embodiments being illustrative and not restrictive.

1. A method of creating a security document, the method comprising the steps of:
(a) encoding the document with a first set of protection marks containing information defining an absolute co-ordinate system across the face of the document; and
(b) encoding the document with a second set of protection marks containing information that (i) identifies at least one region of the document according to the co-ordinate system and (ii) defines at least one security attribute of the content within the defined region;
wherein the first and second sets of protection marks are intermixed across the face of the document and are used together to determine the location of the defined region within the document.

2. A method according to claim 1, wherein the encoding of the document in steps (a) and (b) comprises modulating an attribute of the associated protection marks with the respective information.

3. A method according to claim 1, wherein the information identifying the at least one region is encoded in the second set of marks or in both sets of marks.

4. A method according to claim 1, wherein the security attribute is used to detect tampering with the document in the region.

5. A method according to claim 1, wherein the security attribute is used to detect handwritten additions to the document in the region.

6. A method according to claim 1, wherein the security attribute is used to establish a security level of the region.

7. A method according to claim 1, wherein the security attribute is used to detect tampering and handwritten additions in the region and to establish a security level of the region.

8. A method according to claim 6, wherein the security attribute includes instructions for processing the region.

9. A method according to claim 8, wherein the instructions for processing are directed to a reproducing device and establish whether the region should be masked out when the document is reproduced.

10. A document security system comprising:
an encoder for creating a security document, the encoder comprising:
(a) means for encoding the document with a first set of protection marks containing information defining an absolute co-ordinate system across the face of the document; and
(b) means for encoding the document with a second set of protection marks containing information that (i) identifies at least one region of the document according to the co-ordinate system and (ii) defines at least one security attribute of the content within the defined region;
wherein the first and second sets of protection marks are intermixed across the face of the document and are used together to determine the location of the defined region within the document; and
a decoder for verifying a received security document, the decoder comprising:
(c) means for detecting the first and second sets of protection marks;
(d) means for extracting the absolute coordinate system from the first set of detected marks;
(e) means for extracting the information that (i) identifies the at least one region of the document according to the co-ordinate system and (ii) defines the at least one security attribute of the content within the defined region from the second set of marks; and
(f) means for operating upon the extracted security attribute to thereby verify the received security document.

11. An encoder for creating a security document, the encoder comprising:
(a) means for encoding the document with a first set of protection marks containing information defining an absolute co-ordinate system across the face of the document; and
(b) means for encoding the document with a second set of protection marks containing information that (i) identifies at least one region of the document according to the co-ordinate system and (ii) defines at least one security attribute of the content within the defined region;
wherein the first and second sets of protection marks are intermixed across the face of the document and are used together to determine the location of the defined region within the document.

12. A computer readable storage medium having recorded thereon a computer program for directing a processor to execute a method for creating a security document, the program comprising:
(a) code for encoding the document with a first set of protection marks containing information defining an absolute co-ordinate system across the face of the document; and
(b) code for encoding the document with a second set of protection marks containing information that (i) identifies at least one region of the document according to the co-ordinate system and (ii) defines at least one security attribute of the content within the defined region;
wherein the first and second sets of protection marks are intermixed across the face of the document and are used together to determine the location of the defined region within the document.

13. A security document created by a method comprising the steps of:
(a) encoding the document with a first set of protection marks containing information defining an absolute co-ordinate system across the face of the document; and
(b) encoding the document with a second set of protection marks containing information that (i) identifies at least one region of the document according to the co-ordinate system and (ii) defines at least one security attribute of the content within the defined region;
wherein the first and second sets of protection marks are intermixed across the face of the document and are used together to determine the location of the defined region within the document.

14. A method for verifying a received security document, the method comprising the steps of;
detecting first and second sets of protection marks;
extracting an absolute coordinate system from the first set of detected marks;
extracting information that (i) identifies at least one region of the document according to the co-ordinate system and (ii) defines at least one security attribute of the content within the defined region from the second set of marks; and
verifying the received security document using the extracted security attribute.

15. A method according to claim 14, wherein the verifying step performs at least one of validating the originality of the received document and providing evidence of tampering with the received document.

16. A decoder for verifying a received security document, the decoder comprising;
means for detecting first and second sets of protection marks;
means for extracting an absolute coordinate system from the first set of detected marks;
means for extracting information that (i) identifies at least one region of the document according to the co-ordinate system and (ii) defines at least one security attribute of the content within the defined region from the second set of marks; and
means for verifying the received security document using the extracted security attribute.

17. A decoder for verifying a received security document, the decoder comprising;
a memory for storing a program; and
a processor for executing the program, said program comprising:
code for detecting first and second sets of protection marks;
code for extracting an absolute coordinate system from the first set of detected marks;
code for extracting information that (i) identifies at least one region of the document according to the co-ordinate system and (ii) defines at least one security attribute of the content within the defined region from the second set of marks; and
code for verifying the received security document using the extracted security attribute.

18. A computer program product including a computer readable storage medium having recorded thereon a computer program for directing a processor to execute a method for verifying a received security document, the program comprising;
code for detecting first and second sets of protection marks;
code for extracting an absolute coordinate system from the first set of detected marks;
code for extracting information that (i) identifies at least one region of the document according to the co-ordinate system and (ii) defines at least one security attribute of the content within the defined region from the second set of marks; and
code for verifying the received security document using the extracted security attribute.

19. A document according to claim 13, wherein the encoding of the document in steps (a) and (b) comprises modulating an attribute of the associated protection marks with the respective information.

20. A method according to claim 13, wherein the information identifying the at least one region is encoded in the second set of marks or in both sets of marks.

21. A method according to claim 13, wherein the security attribute is used to detect tampering with the document in the region.

22. A method according to claim 13, wherein the security attribute is used to detect handwritten additions to the document in the region.

23. A method according to claim 13, wherein the security attribute is used to establish a security level of the region.

24. A method according to claim 13, wherein the security attribute is used to detect tampering and handwritten additions in the region and to establish a security level of the region.

25. A method according to claim 23, wherein the security attribute includes instructions for processing the region.

26. A method according to claim 25, wherein the instructions for processing are directed to a reproducing device and establish whether the region should be masked out when the document is reproduced.
